(19) United States
(12) Patent Application Publication
(10) Pub. No.: US 2008/0233669 A1
(43) Pub. Date: Sep. 25, 2008

(54) Method for Manufacturing Light-Emitting Device

(75) Inventors: Yoshiharu Hirakata, Ebina (JP); Yosuke Sato, Isehara (JP); Kohei Yokoyama, Isehara (JP); Hideaki Kuwabara, Isehara (JP); Shunpei Yamazaki, Setagaya (JP)

Correspondence Address: COOK, ALEX, McFARRON, MANZO,;CUMMINGS & MEHLER, LTD., SUITE 2850, 200 WEST ADAMS STREET, CHICAGO, IL, 60606, US

(73) Assignee: Semiconductor Energy Laboratory Co., Ltd.

(21) Appl. No.: 12/050,319

(22) Filed: Mar. 18, 2008

(30) Foreign Application Priority Data
Mar. 22, 2007 (JP) 2007-075433

(51) Int. Cl. H01L 21/00

(52) U.S. Cl. 438/35; 257/E21.001

(57) ABSTRACT

A full-color light-emitting device is achieved with plural kinds of light-emitting elements in each of which a stacked layer of a first material layer formed selectively with a droplet discharge apparatus and a second material layer formed by vapor-deposition method using the conductive-surface plate on which a layer containing an organic compound is formed is provided between a pair of electrodes. The first material layer is a layer in which an organic compound and a metal oxide which is an inorganic compound are mixed. By adjusting the thickness of the first material layer of each light-emitting element, which is different depending on an emission color, a blue light emission component, a green light emission component, or a red light emission component among a plurality of components for white light emission can be selectively emphasized and taken out by light interference phenomenon.

### BACKGROUND OF THE INVENTION

1. Field of the Invention

The present invention relates to a light-emitting device using a light-emitting element which can provide fluorescence or phosphorescence when an electric field is applied to the element in which a film containing an organic compound (hereinafter referred to as an ‘organic compound layer’) is provided between a pair of electrodes, and a manufacturing method thereof. Note that the light-emitting device refers to an image display device, a light emission device, or a light source (including a lighting device). Further, the present invention relates to a manufacturing apparatus of a light-emitting device and a cleaning method of the manufacturing apparatus.

2. Description of the Related Art

In recent years, a light-emitting device having an EL element as a self-luminous light-emitting element has been actively developed. This light-emitting device is also called an organic EL display or an organic light-emitting diode. Such a light-emitting device has advantages in high response speed which is suitable for displaying moving images, low-voltage, low-power-consumption drive, and the like; therefore, the light-emitting device has attracted attention as a next-generation display such as a new-generation mobile phone or portable information terminal (PDA).

For such a light-emitting device in which EL elements are arranged in matrix, a driving method such as passive matrix driving (simple matrix type) or active matrix driving (active matrix type) can be used. However, when the pixel density is increased, the active matrix type where a switch is provided per pixel (per dot) is considered to be advantageous because it can be driven at a lower voltage.

Further, a layer containing an organic compound has a stacked-layer structure typified by a stacked-layer structure of a hole transport layer, a light-emitting layer, and an electron transport layer. Further, EL materials for forming EL layers are roughly classified into low molecular (monomer) materials and high molecular (polymer) materials, and film formation of a low molecular material is performed with a vapor-deposition apparatus.

Note that an EL element includes a layer containing an organic compound (hereinafter referred to as an ‘EL layer’) which can provide luminescence generated when an electric field is applied (electroluminescence), an anode, and a cathode. It is known that, as the luminescence in an organic compound, there are light emission when the excited state is returned to ground state from singlet excited state (fluorescence) and light emission when the excited state is returned to ground state from triplet excited state (phosphorescence).

An organic EL panel having an organic EL element is self-luminous type unlike a liquid crystal display device which needs a backlight, thus it is superior in visibility because high contrast can be easily realized and the viewing angle is large. That is, the organic EL panel is more suitable for a display for outdoor use than a liquid crystal display, and various applications thereof such as a display device of a mobile phone or a digital camera, or the like have been proposed.

In Reference 1 (Japanese Published Patent Application No. Hei 7-240277), a technique in which, when a full-color organic EL panel is manufactured using an organic EL element, the thickness of an anode of ITO and a plurality of organic compound material layers are set such that a desired wavelength of light obtained from a light-emitting layer becomes a peak wavelength is described.

When a full-color organic EL panel is manufactured using three primary colors of R (red), G (green), and B (blue), respective different light-emitting materials of R, G, and B are formed with film-formation chambers so as not to mix any material having a different emission wavelength. Thus, the total period of time (or takt time) taken for manufacture of a full-color organic EL panel has been long.

In addition, an organic light-emitting device in which, without the use of a color filter, resonance of white light emission is performed by light interference phenomenon and then conversion into three colors is performed has been disclosed in each of References 2 (Japanese Published Patent Application No. 2005-93399) and 3 (Japanese Published Patent Application No. 2005-93401).

In addition, the present applicant has disclosed an EL element having a low molecular film so as to be in contact with a high molecular film and a manufacturing method thereof in Reference 4 (Japanese Published Patent Application No. 2002-33195).

In addition, the present applicant has disclosed an EL element having a light emitting layer and an oxide layer containing a transition metal formed by a wet process between a pair of electrodes in Reference 5 (Japanese Published Patent Application No. 2006-190995).

In addition, the present applicant has disclosed a cleaning method in Reference 6 (Japanese Published Patent Application No. 2003-313654).

### SUMMARY OF THE INVENTION

It is an object of the present invention to provide a technique for forming a film with high thickness uniformity, using an apparatus having a relatively simple structure. In addition, it is an object of the present invention to provide a technique for greatly shortening the period of time taken to manufacture a full-color organic EL panel. It is an object of the present invention to reduce the loss of takt time or manufacturing cost with the use of these techniques.

In this specification, it is proposed to achieve a full-color light-emitting device with plural kinds of light-emitting elements in each of which a stacked layer of a first material layer formed selectively with a droplet discharge apparatus and a second material layer formed by a novel film-formation method is provided between a pair of electrodes. Note that the second material layer includes at least a single layer of white light emission or a stacked layer of white light emission obtained by synthesis (e.g., a staked layer of a red-light-emitting layer, a green-light-emitting layer, and a blue-light-emitting layer). The thickness of the first material layers in the plural kinds of light-emitting elements is different depending on an emission color such that a desired emission color is obtained. By adjusting the thickness of the first material layer of each light-emitting element, which is different depending on an emission color, a blue light emission component, a green light emission component, or a red light emission component among a plurality of components for white light emission can be selectively emphasized and taken out by light interference phenomenon.

Further, the first material layer is a layer in which an organic compound and a metal oxide which is an inorganic compound are mixed. The metal oxide is at least one kind of molybdenum oxide, vanadium oxide, and rhenium oxide. For adjustment of thickness of the first material layer, an ink jet device is typically used. Thus, a material liquid (liquid containing a metal oxide) which can be discharged from a droplet discharge head of the ink jet device is prepared. Ink jet device can control film thickness precisely by adjustment of a minute amount of a droplet.

The first material layer in which an organic compound and a metal oxide which is an inorganic compound are mixed is desirable in that a voltage to be applied for obtaining a predetermined current (also referred to as a driving voltage) is not increased even if the thickness thereof is increased. Accordingly, low power consumption of a light-emitting device can be achieved.

Further, the second material layer is formed by a novel film-formation method in a short period of time. A film-formation apparatus in which at least a plate over which the second material layer has been formed, a substrate on which film formation is performed (hereinafter referred to as a ‘film-formation substrate’), and a heat source (e.g., a hot plate or a flash lamp) are included in a vacuum chamber which can be made in a reduced-pressure state is used.

Note that, in this specification, the plate refers to a rectangular flat plate, and preferably, a flat plate with 5 inches or more (diagonal), and includes in its category a metal plate and an insulating substrate (e.g., a glass substrate or a quartz substrate) on which a conductive film is formed; it is referred to as a ‘plate’ for convenience in order to be distinguished from the film-formation substrate. Further, it is preferable that the plate have heat resistance because the plate is heated.

Here, a procedure of the novel film-formation method is explained briefly. In the vacuum chamber, the plate over which the second material layer has been formed and the film-formation substrate over which the first material layer has been formed are disposed so as to face each other at a short distance so as not to be in contact with each other. They are set such that the surface of the second material layer and the surface of the first material layer face each other. The film-formation chamber is made in a reduced-pressure state and the plate is heated rapidly by heat conduction or heat radiation using the heat source, whereby the second material layer over the plate is vaporized in a short period of time, and formed over the first material layer so that the second material layer is stacked.

By this novel film-formation method, film thickness uniformity can be achieved without the use of a film thickness monitor, thus the takt time can be shortened. Further, there is no limitation on the size of the film-formation substrate, and the film thickness uniformity can be achieved even in the case of a large-area substrate with over 1 m per side. Furthermore, the use efficiency of a vapor-deposition material and throughput can be drastically improved.

Further, in this novel film-formation method, adjustment of vapor-deposition rate by using a film thickness monitor is not needed to be performed, thus the film-formation apparatus can be totally automated. Further, one plate is used for film formation of one layer; that is, it can be said that a material is replenished every time by the amount which is needed for one film formation. In a conventional vapor-deposition apparatus, a material is manually replenished after the film-formation chamber is made in the atmospheric pressure state once a material stored in a vapor-deposition source is run out. Since the capacity of the film-formation chamber is large and the material use efficiency is low in the conventional vapor-deposition apparatus, replenishment is frequently performed.

In a conventional vapor-deposition method, in the case of a large-area substrate, film thickness distribution may occur concentrically with a central focus on a central portion of a substrate which is overlapped with and over a vapor-deposition source since the vapor-deposition source is small as compared with the size of the substrate.

Further, in the conventional vapor-deposition method, adjustment with a film thickness monitor or the like is performed until the vapor-deposition rate becomes stable and vapor deposition starts after the vapor-deposition rate is stabilized. Thus, a vaporized material is not deposited on the film-formation substrate but is attached to an inner wall or the like in a film-formation chamber until the vapor-deposition rate becomes stable. In the case where the material is attached to the inner wall or the like in the film-formation chamber, manual cleaning of the film-formation chamber which is frequent and for a long period of time is needed. As described above, in the conventional vapor-deposition method, the loss of takt time and vapor-deposition material has occurred.

Further, if the first material layer is formed by not a droplet discharge method typified by an ink jet method but a spin-coating method or a dip-coating method, the film formation is performed over an entire surface of a substrate, and thus the first material layer is formed even in a portion where an electrode is taken out (also called a terminal portion), which causes a disadvantage in forming a contact with an external circuit. If the ink jet method is used, the first material layer can be formed in a region other than the portion where an electrode is taken out and the thickness of the film can be selectively varied depending on a region. Furthermore, in the novel film-formation method, since film formation of the second material layer is performed on the first material layer at a position to face the plate provided with the second material layer, selective film formation can be performed by alignment so as not to overlap the portion where an electrode is taken out and the plate with each other.

Further, if patterning of the second material layer over the plate is performed in advance, the patterned shape of the second material layer can be reflected when the second material layer is deposited over the first material layer as well.

The technique in which resonance of white light emission is performed by light interference phenomenon and then conversion into three colors is performed disclosed in each of References 2 (Japanese Published Patent Application No. 2005-93399) and 3 (Japanese Published Patent Application No. 2005-93401) is different greatly from the manufacturing method of the present invention in that wet etching or dry etching using an etching mask is performed at least three times in order to adjust the optical path length.

A structure of the present invention disclosed in this specification is a method for manufacturing a semiconductor device having a red-light-emitting element, a blue-light-emitting element, and a green-light-emitting element, and a method for manufacturing a light-emitting device in which a first electrode is formed over a first substrate, a first material layer is selectively formed over the first electrode by a droplet discharge method, a surface of a second substrate provided with a film containing a second material and a surface of the first substrate provided with the first material layer are disposed so as to face each other, the second substrate is heated so that a second material layer containing a light-emitting material is formed over the first material layer, and a second electrode is formed over the second material layer.

In the above-described structure, the first material layer of the red-light-emitting element, the first material layer of the blue-light-emitting element, and the first material layer of the blue-light-emitting element are different in thickness.

Further, in the above-described structure, heating of the second substrate is performed by heating with a heater or a lamp, or heating by voltage application to the second substrate.

Further, in the above-described structure, the first electrode or the second electrode is formed of a light transmitting material in order to obtain a microcavity effect. Furthermore, the first electrode is formed of a reflective material, and the thickness of the first material layer varies depending on a color such that an emission color is changed by interference between white light emitted from the second material layer and reflected light reflected on the first electrode; or the second electrode is formed of a reflective material, and the thickness of the first material layer varies depending on a color such that an emission color is changed by interference between white light emitted from the second material layer and reflected light reflected on the second electrode.

Further, in the above-described structure, the first material layer contains a metal oxide and the metal oxide is molybdenum oxide, vanadium oxide, or rhenium oxide.

The present invention achieves at least one of the above-described objects.

Further, the present invention is not limited to the full-color display device using three primary colors, and the present invention may be a full-color display device using color cyan or magenta as well. Further alternatively, the present invention may be a full-color display device using four pixels of R, G, B, and W.

Further, a novel cleaning method is also provided in this specification. The structure is a cleaning method for removing an organic compound which has been attached to inside a film-formation chamber, and a cleaning method in which a mask and a conductive substrate are put into the film-formation chamber such that the conductive substrate faces the mask, and plasma is generated to clean an inner wall of the film-formation chamber or the mask.

The structure of the above-described cleaning method is a cleaning method in which the plasma is generated between the mask and an electrode provided between the mask and the vapor-deposition source.

Further, according to the structure of the above-described cleaning method, the plasma is generated by exciting at least one kind of gases of Ar, H, F; NF₃, and O.

Cleaning may be performed as follows: plasma is generated with a plasma generator having at least a pair of electrodes and a high-frequency power source in a film-formation chamber, and a deposition which has been attached to the inner wall of the film-formation chamber or a vapor-deposition mask is evaporated and exhausted to outside the film-formation chamber. By the above-described structure, inside the film-formation chamber can be cleaned without exposure to air at the time of maintenance.

According to the novel film-formation method, the capacity of the film-formation chamber can be reduced as compared to that of the conventional vapor-deposition apparatus. Thus, when plasma is generated, inside the film-formation chamber can be cleaned in a short period of time.

Further, as one electrode used for plasma generation, a conductive plate can be used. Thus, if a conductive plate is used as the plate over which a second material layer is formed, the plate after the second material layer is evaporated can be used as one electrode used for plasma generation.

A method for manufacturing a light-emitting device disclosed in this specification is a method for manufacturing a light-emitting device in which a layer containing an organic compound is formed over one surface of a substrate having a conductive surface (hereinafter, referred to as a ‘conductive-surface substrate’) in a first film-formation chamber, a substrate having a first electrode over one surface which faces the layer containing an organic compound is held in a second film-formation chamber, a mask is held between the conductive-surface substrate and the substrate having the first electrode in the second film-formation chamber, the layer containing an organic compound is evaporated in the second film-formation chamber so that a material layer containing an organic compound is formed over the first electrode, a second electrode is formed over the layer containing an organic compound in the second film-formation chamber, the substrate having the first electrode is taken out from the second film-formation chamber, and plasma is generated between the mask and the conductive-surface substrate in the second film-formation chamber.

In the above-described manufacturing method, the plasma is generated between the mask and the conductive-surface substrate to clean an inner wall of the second film-formation chamber or the mask.

Alternatively, a first material layer may be formed over a first electrode by an ink jet method, and the first material layer provided with the first electrode may be carried into and disposed in a second film-formation chamber so as to face a conductive-surface substrate, provided with a second material layer, and then vapor deposition may be performed. Furthermore, after the vapor deposition, a film-formation substrate may be carried out from the second film-formation chamber, and then plasma may be generated between the mask and the conductive-surface substrate to perform cleaning in the second film-formation chamber. In this way, cleaning of a plate after the second material layer is evaporated can also be performed, and the plate can be used repeatedly by repeating formation of the second material layer.

Further, cleaning can be performed efficiently. The work can be performed smoothly by the following: a film-formation substrate is carried out of the film-formation chamber after film formation is performed on a plurality of substrates, and cleaning inside the film-formation chamber is performed with the use of a plate which has been last used, as an electrode for plasma generation. This cleaning work can also be totally automated; for example, a manufacturing apparatus can be programmed to perform cleaning per certain number of treated substrates so that film formation and cleaning can be totally automated from start to finish.

Further, as the other electrode used for plasma generation, a conductive mask can be used. Of course, cleaning of the mask which has been used for vapor deposition can also be performed. It is preferable that, as the mask, a metal material which is hard to be transformed by heat (i.e., the coefficient of thermal expansion is low) and can withstand the substrate temperature (T₁) (e.g., a high-melting metal such as tungsten, tantalum, chromium, nickel, or molybdenum, an alloy containing any of these elements, stainless steel, inconel, hastelloy, or the like) be used.

Further, the full-color display device of the present invention in which first material layers having different thicknesses are manufactured by an ink jet method and a second material layer formed by a coating method can be stacked can adapt to increase in size of a substrate and is suited for mass production.

Further, a full-color display device can be achieved by varying the thickness of a layer in which an organic compound and a metal oxide which is an inorganic compound are mixed, depending on each of R, G, and B. Even if the thickness of the layer is varied depending on each of R, G, and B, the voltage which is to be applied for obtaining a predetermined current (also referred to as a driving voltage) is not increased. Thus, low power consumption of a full-color display device can be achieved.

### BRIEF DESCRIPTION OF THE DRAWINGS

FIGS. 1A to 1C are diagrams showing a manufacturing process of a full-color display device.

FIGS. 2A and 2B are cross-sectional views each of a full-color display device.

FIG. 3 is a cross-sectional view of a film-formation apparatus having a cleaning mechanism.

FIG. 4 is a cross-sectional view of a manufacturing apparatus having a film-formation apparatus.

FIG. 5 is a graph showing thermal rising of a substrate.

FIG. 6 is a top-plane view of a manufacturing apparatus.

FIG. 7 is a cross-sectional view of a manufacturing apparatus.

FIG. 8 is a cross-sectional view of a film-formation chamber.

FIG. 9A is a top-plane view of a passive matrix light-emitting device and FIGS. 9B and 9C are cross-sectional views thereof.

FIG. 10 is a perspective view of a passive matrix light-emitting device.

FIG. 11 is a top-plane view of a passive matrix light-emitting device.

FIGS. 12A and 12B are views of a light-emitting device.

FIGS. 13A to 13E are diagrams illustrating examples of an electronic appliance.

### DETAILED DESCRIPTION OF THE INVENTION

Embodiment modes and embodiments of the present invention will be described below.

### EMBODIMENT MODE 1

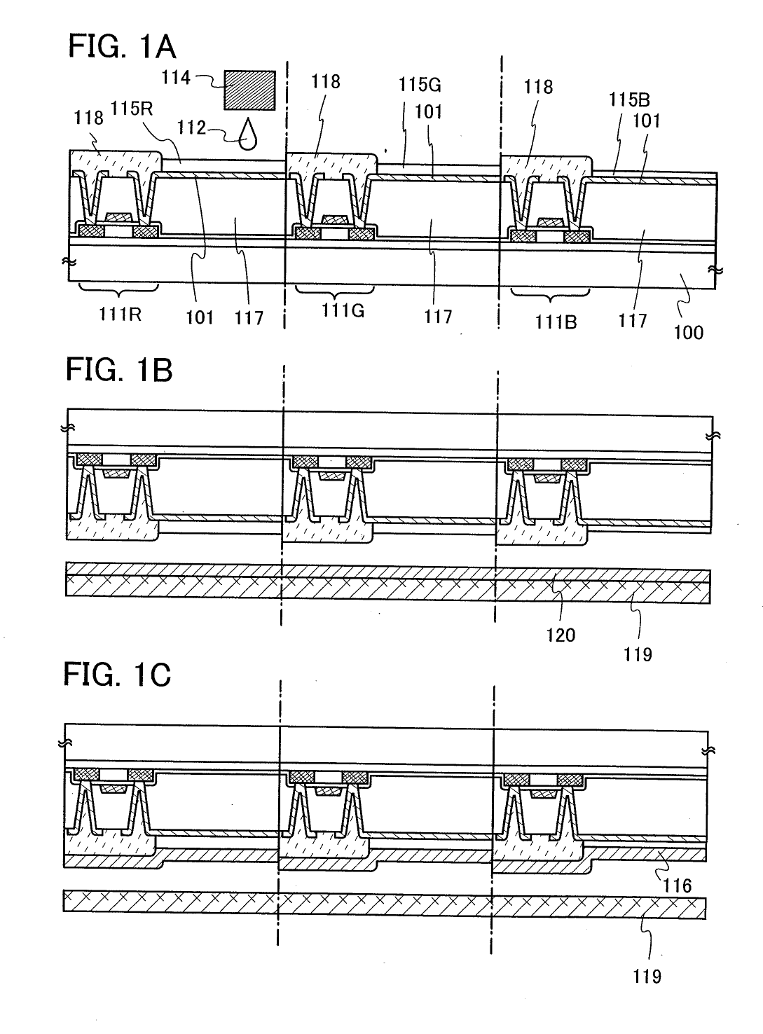

First, a plurality of TFTs is manufactured over a substrate having an insulating surface 100. The TFTs are transistors for controlling current supply to respective-color-light-emitting elements. In each of the TFTs, a semiconductor film, a gate insulating film covering the semiconductor film, a gate electrode, and an interlayer insulating film over the gate electrode are provided. TFTs 111R, 111G, and 111B are covered with an interlayer insulating film 117, and a bank 118 having an opening is formed over the interlayer insulating film 117 as shown in FIG. 1A. A first electrode 101 is partially exposed in the opening of the bank 118.

The interlayer insulating film 117 can be formed of an organic resin material, an inorganic insulating material, or an insulator including a Si—O—Si bond which is formed from a siloxane-based material (hereinafter referred to as a siloxane insulator). Siloxane insulator contains hydrogen as a substituent and may contain at least one kind of fluorine, an alkyl group, and a phenyl group as another substituent. Further, a material called a low dielectric constant material (low-k material) may be used as well for the interlayer insulating film 117.

The first electrode 101 is formed of a non-light-transmitting material, i.e., a highly reflective material. Specifically, a metal material such as aluminum (Al), gold (Au), platinum (Pt), nickel (Ni), tungsten (W), chromium (Cr), molybdenum (Mo), iron (Fe), cobalt (Co), copper (Cu), or palladium (Pd) can be used. Further, a stacked-layer structure of indium tin oxide (ITO), indium tin oxide containing silicon oxide, and indium oxide containing zinc oxide at 2 to 20% that are light-transmitting materials may be used as well. Note that the material of the first electrode is not limited to these.

The bank 118 can be formed of an organic resin material, an inorganic insulating material, or a siloxane insulator. For example, acrylic, polyimide, polyamide, or the like can be used as the organic resin material, and silicon oxide, silicon nitride oxide, or the like can be used as the inorganic insulating material. With the bank 118, short circuiting between the first electrode 101 and a second electrode formed later can be prevented.

Next, first layers 115R, 115G, and 115B are formed over the exposed first electrodes 101 by an ink jet method. As shown in FIG. 1A, the thickness thereof is varied depending on each of a red pixel region, a green pixel region, and a blue pixel region. The red pixel region, the green pixel region, and the blue pixel region are three regions which are partitioned with the bank 118. The film thickness is adjusted by the amount of a droplet or the number of droplets of a droplet 112 discharged from a head 114 of an ink jet device.

The first layers are formed by the following: an organic compound (or a solution of an organic compound) is mixed with prepared sol and stirred so that a solution containing transition metal alkoxide and an organic compound is obtained; this solution is discharged with the ink jet device; and after that, baking is performed.

It is preferable that the organic compound be a compound which is superior in hole transporting properties, and be an organic compound having an arylamine skeleton. Specifically, the following can be given as examples thereof, but the present invention is not limited to these: 4,4′,4″-tris(N,N-diphenylamino)triphenylamine (abbrev. TDATA), 4,4′,4″-tris[N-(3-methylphenyl)-N-phenylamino]triphenylamine (abbrev. MTDATA), 1,3,5-tris[N,N-bis(3-methylphenyl)amino]benzene (abbrev. m-MTDAB), N,N′-diphenyl-N,N′-bis(3-methylphenyl)-1,1′-biphenyl-4,4′-diamine (abbrev. TPD), 4,4′-bis[N-(1-naphthyl)-N-phenylamino]biphenyl (abbrev. NPB), 4,4′-bis(N-{4-[N′,N′-bis(3-methylphenyl)amino]phenyl}-N-phenylamino)biphenyl (abbrev. DNTPD), 4,4′,4″-tris(N-carbazolyl)triphenylamine (abbrev. TCTA), poly(4-vinyltriphenylamine) (abbrev. PVTPA), and the like.

For the sol, a transition metal alkoxide of titanium, vanadium, molybdenum, tungsten, rhenium, ruthenium, or the like is used. The sol is prepared by adding water and a chelating agent such as β-diketone as a stabilizer into a solution in which the transition metal alkoxide is dissolved in a proper solvent. Further, as the solvent, for example, tetrahydrofuran (THF), acetonitrile, dichloromethane, dichloroethane, anisole, or a mixed solvent of these can be used, as well as lower alcohol such as methanol, ethanol, n-propanol, i-propanol, n-butanol, or sec-butanol; however, the present invention is not limited to these. Further, as a compound which can be used as the stabilizer, β-diketone such as acetylacetone, ethyl acetoacetate, or benzoylacetone can be given, for example. The stabilizer which is provided for preventing precipitation in the sol is not necessarily needed. Further, the amount of water to be added is preferably 2 or more and 6 or less equivalent weight with respect to a metal alkoxide since the metal of alkoxide is generally any of diatomic to hexatomic. However, water which is used for controlling the progress of reaction of the metal alkoxide is not necessarily needed.

Further, in order to enhance the film quality, a material serving as a binder (a binder substance) may also be added into the first layers. In particular, in the case where a low molecular compound (specifically, a compound with molecular weight of 500 or less) is used as an organic compound, the binder substance is needed in consideration of formation to be a film. Of course, also in the case where a high molecular compound is used, the binder substance may be added as well. As examples of the binder substance, polyvinyl alcohol (abbrev. PVA), polymethyl methacrylate (abbrev. PMMA), polycarbonate (abbrev. PC), a phenol resin, and the like are given.

Next, a substrate 119 over which a layer containing an organic compound 120 has been formed is prepared. The layer containing an organic compound 120 is a layer having a function of emitting light and contains at least a light-emitting substance. A known material can be used as the light-emitting substance. Further, another material may also be contained in addition to the light-emitting substance.

The substrate 119 and the substrate 100 are disposed so as to face each other as shown in FIG. 1B, and the substrate 119 is heated. By heating the substrate 119 in a reduced pressure, the layer containing an organic compound formed over the substrate 119 is evaporated such that a second layer 116 can be formed over the first layers 115R, 115G, and 115B as shown in FIG. 1C. In this embodiment mode, holes are transported from the first layers 115R, 115Q, and 115B and electrons are transported from a second electrode formed later to the second layer 116, these carriers (electrons and holes) are recombined, and thus, the light-emitting organic compound contained in the second layer 116 is excited. White light is emitted when the excited state returns to the ground state.

Further, in the case where white light emission is obtained with the second layer 116 having a stacked-layer structure, the same number of the substrates 119 as the number of layers to be stacked may be prepared and the stacked-layer structure may be formed by sequential one-by-one formation. For example, three layers of a red-light-emitting layer, a green-light-emitting layer, and a blue-light-emitting layer may be stacked to form the second layer 116 such that white light is generated.

In this way, in each opening of the bank 118, the first electrode 101, any of the first layers 115R, 115G, and 115B, and the second layer 116 are stacked sequentially. Note that, in this embodiment mode, the case where, of the two electrode of the first electrode 101 and the second electrode 102 included in each light-emitting element, one of the electrodes whose potential can be controlled by a transistor is an anode and the other is a cathode is described.

Since increase in driving voltage can be suppressed even if the thickness of the first layer is increased, the thickness of the first layer can be set as desired, and the emission color can be changed by varying the thickness of the first layer. Further, the thickness of each of the first layers 115R, 115G, and 115B can be set such that the efficiency of taking light emission from the second layer 116 out is improved. Further, the thickness of each of the first layers 115R, 115G, and 115B can be set such that the color purity of light emission from the second layer 116 is improved.

Next, the second electrode 102 is formed over the second layer 116 by a sputtering method or a vapor-deposition method. For the second electrode 102, a stacked layer of a thin metal film of Ag, Mg, or the like with a thickness which is small enough to transmit light emission and a transparent conductive film (e.g., a film of ITO, indium oxide containing zinc oxide at 2 to 20%, indium tin oxide containing silicon, or zinc oxide (ZnO)) is used.

Further, a layer having a function of transporting electrons to the second layer 116, i.e., a third layer may be formed between the second layer 116 and the second electrode 102.

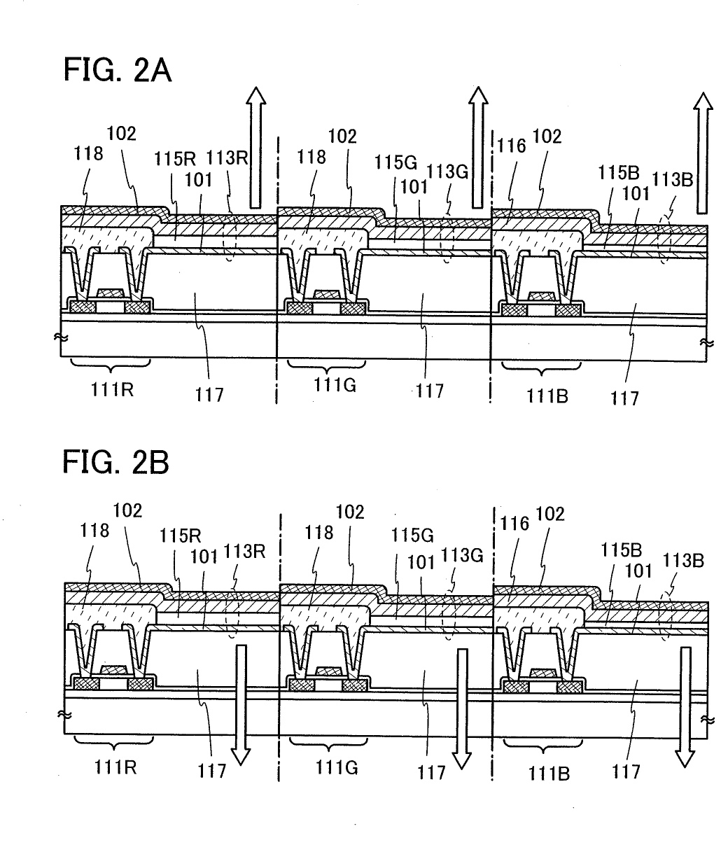

As shown in FIG. 2A, the first electrode 101 and the second electrode 102 are provided so as to face each other, and the first electrode 101, any of the first layers 115R, 115G, and 115B, the second layer 116, and the second electrode 102 are stacked sequentially. When the first electrode 101 has reflecting properties and the second electrode 102 has light-transmitting properties, the structure of taking light out in the direction denoted by an arrow shown in FIG. 2A is obtained. Further, the emission color is changed depending on each of the red pixel region, the green pixel region, and the blue pixel region, using difference of thickness of the first layer. For example, in a green-light-emitting element 113G, the thickness of the first layer is set such that light interference is generated between the pair of electrodes and the light path length is made to be reinforced at a wavelength of color green by this resonance. Mainly the thickness of the first layer 115G is adjusted such that the light path length is made to be weakened at wavelengths other than the wavelength of color green.

Similarly, in a red-light-emitting element 113R, the thickness of the first layer is set such that light interference is generated between the pair of electrodes and the light path length is made to be reinforced at a wavelength of color red by this resonance. Mainly the thickness of the first layer 115R is adjusted such that the light path length is made to be weakened at wavelengths other than the wavelength of color red.

Similarly, in a blue-light-emitting element 113B, the thickness of the first layer is set such that light interference is generated between the pair of electrodes and the light path length is made to be reinforced at a wavelength of color blue by this resonance. Mainly the thickness of the first layer 115B is adjusted such that the light path length is made to be weakened at wavelengths other than the wavelength of color blue.

Through the above-described process, a full-color display device can be manufactured. The first layers having different thicknesses can be formed by one film-formation process with an ink jet device and the second layer can also be formed by one film-formation process, which realizes manufacture in a short period of time.

FIG. 2B shows an example of the structure of taking light out in the direction opposite to the direction of FIG. 2A. When the first electrode 101 has light-transmitting properties and the second electrode 102 has reflecting properties, the structure of taking light out in the direction denoted by an arrow shown in FIG. 2B is obtained.

### EMBODIMENT MODE 2

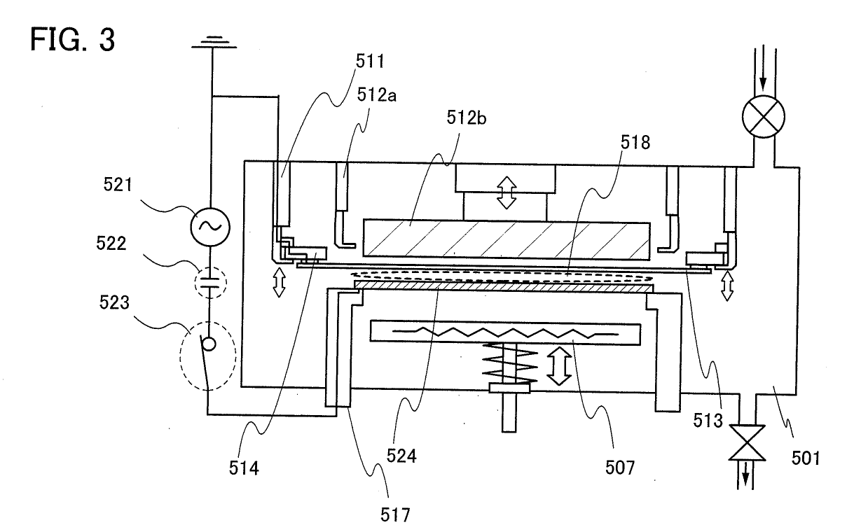

In this embodiment mode, one example of a film-formation apparatus having a plasma generator for cleaning is shown in FIG. 3.

FIG. 3 is a cross-sectional view showing one example of a film-formation apparatus having a cleaning function. A film-formation chamber 501 is coupled to a vacuum exhaust process chamber, which is preferably evacuated by vacuum exhaust so as not to mix moisture or the like. Further, the film-formation chamber 501 is coupled to a reactive gas introduction system for introducing a gas for cleaning. Further, the film-formation chamber 501 is coupled to an inert gas introduction system for introducing an inert gas so that inside the film-formation chamber is made in the atmospheric pressure state.

Further, as a material for an inner wall of the film-formation chamber 501, aluminum, stainless steel (SUS: Steel special Use Stainless), or the like which has been electropolished to have a mirror surface is used because the degree of adsorption of an impurity such as oxygen or moisture can be reduced by reducing the surface area of the inner wall. Accordingly, the degree of vacuum in the film-formation chamber can be maintained to 10⁻⁵ to 10⁻⁶ Pa. Further, a material such as ceramics which has been processed so that there are quite few air holes is used as an inner member. Note that such a material has preferably surface smoothness where the center line average roughness is 3 nm or less. Further, the inner wall of the film-formation chamber 501 is preferably coated with a material which is not damaged by the gas introduced for plasma generation, or a protective film.

In this embodiment mode, an example in which plasma 518 is generated between a mask 513 which is connected to an RF power source 521 which is a high-frequency power source via a capacitor 522 and a cleaning plate 524 is described. Note that electrodes for plasma generation are not limited to the mask and the cleaning plate; an electrode may be provided with an alignment mechanism 512b and used as one electrode, and/or an electrode may be provided with a heater 507 and used as one electrode.

The thin-plate mask 513 having a pattern opening is fixed to a frame-shaped mask frame 514 by adhesion or weld. Since the mask 513 is a metal mask, the shape of the periphery of the opening of the mask becomes sharp, that is, the cross-sectional surface thereof is not perpendicular but is tapered when the opening is formed by processing the mask. Thus, much plasma tends to be generated in the periphery of the opening of the mask so that a portion which needs cleaning of an attached substance the best, that is, the periphery of the opening where the mask alignment is decreased if the attached substance is attached can be cleaned.

A mask holder 511 for electrically connecting the mask 513 to the RF power source 521 is provided. Of course, the flame-shaped mask frame 514 is also formed of a conductive material. Although only a current pathway which connects the one mask holder 511 to one holder 517 is shown in FIG. 3, a plurality of mask holders which is in contact with one mask may be electrically connected to the RF power source 521.

Further, the holder 517 is electrically connecting the cleaning plate 524 to the RF power source 521 via the capacitor 522 and a switch 523. Although only the current pathway which connects the one mask holder 511 to the one holder 517 is shown in FIG. 3, a plurality of holders which is in contact with one plate may be electrically connected to the RF power source 521 via the capacitor 522 and the switch 523.

At the time of cleaning, the cleaning plate 524 is put into the film-formation chamber in which the pressure has been reduced, without exposure to air and disposed at a position so as to face the mask 513. The distance between the cleaning plate 524 and the mask 513 is adjusted by the mask holder 511. Then, a gas is introduced into the film-formation chamber 501. As the gas introduced into the film-formation chamber 501, at least one kind of gases of Ar, H, F, NF₃, and O may be used. Then, the switch 523 is turned on, and a high-frequency electric field is applied to the mask 513 from the RF power source 521 to excite the gas (e.g., Ar, H, F, NF₃, and/or O), so that the plasma 518 is generated. In this way, the plasma 518 is generated in the film-formation chamber 501, and an organic matter which has been attached to the inner wall of the film-formation chamber or the mask 513 is evaporated and exhausted to outside the film-formation chamber. With the film-formation apparatus shown in FIG. 3, inside the film-formation chamber can be cleaned without exposure to air at the time of maintenance.

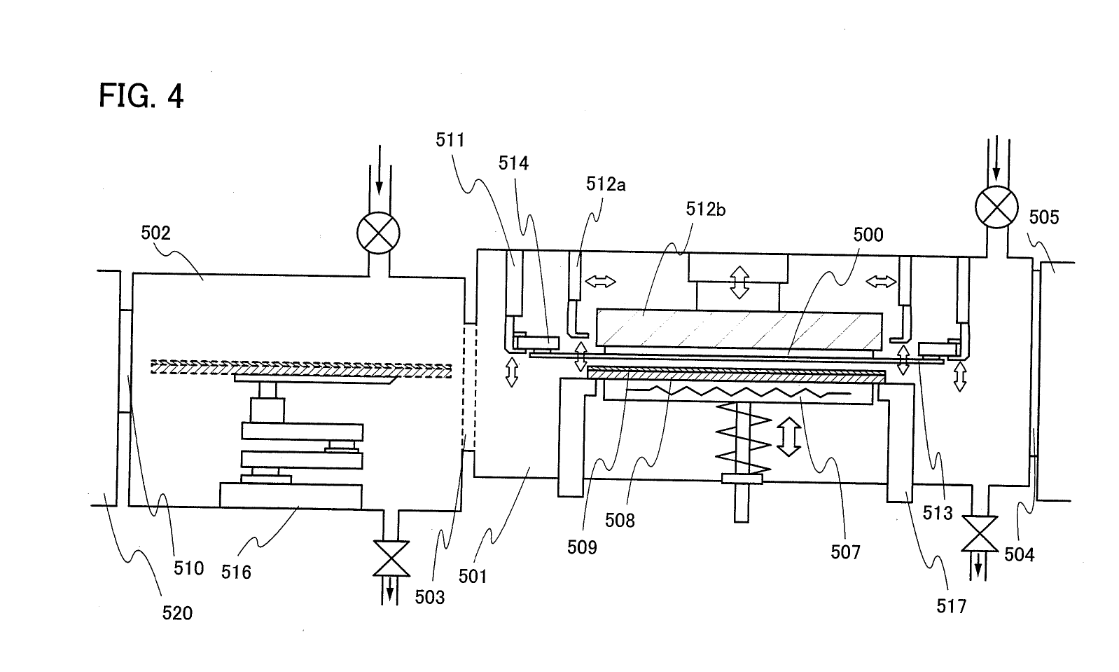

Further, as shown in FIG. 4, a procedure for film formation of a second material layer 509 over a substrate 500 is described using a cross-sectional view of a manufacturing apparatus. Note that the film-formation chamber 501 of a manufacturing apparatus shown in FIG. 4 is similar to that shown in FIG. 3. In FIG. 4, the same portions to FIG. 3 are denoted by the same reference symbols.

In FIG. 4, the film-formation chamber 501 is coupled to an installation chamber 502 and a carrier chamber 505. Further, the installation chamber 502 is coupled to a coating chamber 520. Further, gate valves 503, 504, and 510 are provided between the film-formation chamber 501 and the installation chamber 502, between the film-formation chamber 501 and the carrier chamber 505, and between the installation chamber 502 and the coating chamber 520, respectively.

The coating chamber 520 is a film-formation chamber for forming the second material layer 509 over a plate 508. In the coating chamber 520, the second material layer 509 is applied by a spin-coating method or a spray method in the atmospheric pressure or a reduced pressure and then baked. A load chamber for introducing the plate 508 and/or a heating chamber for baking may also be coupled to the coating chamber 520.

The installation chamber 502 is coupled to a vacuum exhaust process chamber such that inside the installation chamber 502 can be evacuated by vacuum exhaust. Further, the installation chamber 502 is coupled to an inert gas introduction system for introducing an inert gas so that inside the film-formation chamber is made in the atmospheric pressure state. Further, the installation chamber 502 is provided with a carrier unit 516 such as a carrier robot arm, and the substrate 500 or the plate 508 is carried between the coating chamber 520 and the film-formation chamber 501 with the use of the carrier unit 516. Further, the installation chamber 502 may be provided with a holder for stocking a plurality of the plates 508 or the substrates 500. Further, a load chamber for introducing the substrate 500 may be coupled to the installation chamber 502.

Note that a first material layer selectively formed by an ink jet method has been provided over the substrate 500, through not shown. As described in Embodiment Mode 1, the thickness of the first material layer is varied depending on each of the red pixel region, green pixel region, and blue pixel region. The film thickness is adjusted by the amount of a droplet or the number of droplets discharged from a head of an ink jet device.

The film-formation chamber 501 has a first holding means for holding the substrate 500 which is a film-formation substrate and a second holding means for holding the plate 508 over which the second material layer has been formed. In the film-formation chamber 501, an alignment mechanism 512a and the alignment mechanism 512b are provided as the first holding means. In addition, in the film-formation chamber 501, the holder 517 is provided as the second holding means.

Further, selective film formation can be performed with the mask 513 in the film-formation chamber 501. Alignment with the substrate 500 is performed with the mask holder 511 for supporting the mask 513 and the mask frame 514. First, the substrate 500 which has been carried is supported by the alignment mechanism 512a and installed in the mask holder 511. Then, the substrate 500 provided over the mask 513 is moved toward the alignment mechanism 512b so that the substrate 500 in addition to the mask 513 is attracted and fixed by magnetic force. Note that the alignment mechanism 512b is provided with a permanent magnet (not shown) or a heating means (not shown).

Further, the carrier chamber 505 is coupled to a vacuum exhaust process chamber such that inside the carrier chamber 505 can be evacuated by vacuum exhaust and can be made in the atmospheric pressure state by introduction of an inert gas. Further, the carrier chamber 505 is provided with a carrier unit such as a carrier robot arm, and the substrate 500 after completion of film formation is carried from the film-formation chamber 501 to an unload chamber with the use of the carrier unit 516. Further, the carrier chamber 505 may be provided with a holder for stocking a plurality of the substrates 500 after completion of film formation.

When the plate 508 is disposed on the holder in the film-formation chamber 501, the plate 508 is installed in the second holding means in the film-formation chamber 501 from the coating chamber 520 with the use of the carrier unit 516 provided in the installation chamber 502. In this way, by provision of the installation chamber 502 and switching as appropriate between vacuum and atmospheric pressure in the installation chamber, inside the film-formation chamber 501 can remain the vacuum state.

The main structure of the manufacturing apparatus is as described above, and one example of a procedure for film formation is described below.

First, coating is performed on the plate 508 by a spin-coating method in the coating chamber 520 and baking is performed such that the second material layer 509 is formed.

Then, the plate 508 is carried into the installation chamber 502 with the carrier unit 516, and the gate valve 510 is closed. Then, the installation chamber is evacuated until the degree of vacuum reaches that of the film-formation chamber 501. Then, the gate valve 503 is opened, and the plate 508 is put on the holder 517. Note that a pin or a clip for fixing the plate 508 to the holder 517 may be provided so as to prevent misalignment of the plate 508.

Next, the substrate 500 and the plate 508 are kept to be parallel to each other, and the distance between the substrate 500 and the plate 508 is fixed in the range of 0.5 mm to 30 mm both inclusive by adjustment with the alignment mechanism 512b. Note that they are disposed such that the first material layer which has been provided for the substrate 500 and the second material layer which has been provided for the plate 508 face each other.

Next, the heated heater 507 is moved toward the plate 508 to heat the plate 508. In FIG. 4, the heater 507 capable of up-and-down movement under the plate 508 is used. Although the heater is basically set to be fixed at a predetermined temperature, the temperature may be controlled so that the temperature is raised or lowered in the range by which the takt time is not affected.

By moving the heater 507 which is a heat source toward the plate 508, the plate 508 is instantaneously heated and the second material layer 509 is evaporated by direct heat conduction in a short period of time so that film formation is performed on one surface of the substrate 500, that is, the surface which faces the plate 508. This period of time from the movement of the heater 507 to completion of film formation can be short which is less than one minute.

Film formation is completed through the above-described procedure. In this way, film formation can be performed in a short period of time without using a film thickness monitor.

Furthermore, a procedure for performing cleaning successively after film formation is described below. If a conductive material is used for the plate 508, the plate 508 can be used as the cleaning plate 524.

A second material layer is formed over a plate made from a conductive material in the coating chamber 520, the plate is introduced into the film-formation chamber 501 and film formation on the substrate 500 is performed, and the substrate 500 is carried to the carrier chamber 505 without making the pressure the atmospheric pressure. At this stage, a mask and the plate are left in the film-formation chamber. Then, a cleaning gas such as Ar, H, F, NF₃, or O is introduced into the film-formation chamber 501, and plasma is generated with the left mask and plate as a pair of electrodes. By thus doing, cleaning can be performed smoothly.

Further, the heat source shown in FIG. 4 is not limited to the heater 507 as long as it is a heating means capable of uniform heating in a short period of time. For example, a lamp may be used as the heat source. In this case, the lamp is fixed under the plate and immediately after the lamp is lit, film formation is performed on the bottom surface of the substrate 500. With the lamp, the period of time from start to completion of film formation can be short which is less than 30 seconds.

As the lamp, a discharge lamp such as a flash lamp (e.g., a xenon flash lamp or a krypton flash lamp), a xenon lamp, or a metal halide lamp, or an exothermic lamp such as a halogen lamp or a tungsten lamp can be used. With the flash lamp, since a large area can be irradiated with light with extremely high intensity in a short period of time (0.1 to 10 msec) repeatedly, efficient and uniform heating can be performed regardless of the area of the plate. Further, the flash lamp can control heating of the plate by change of the interval of emission time. Furthermore, the running cost can be suppressed because of a long life and low power consumption at the time of waiting for light emission of the flash lamp. Further, with the flash lamp, immediate heating is easily performed so that an above/below mechanism, a shutter, or the like in the case of using the heater can be simplified. Therefore, further reduction in size of film-formation apparatus can be realized. Note that a mechanism by which the flash lamp can move up and down for adjustment of the heating temperature depending on a material of the plate may be employed.

Further, the lamp is not necessarily disposed inside the film-formation chamber 501 but may be disposed outside the film-formation chamber; in this case, part of an inner wall of the film-formation chamber is formed of a light-transmitting member. If the lamp is disposed outside the film-formation chamber, maintenance such as exchange of a light valve of the lamp can be simplified.

Further, instead of using the heater 507 as a heat source shown in FIG. 4, heating may be performed by generating Joule heat with a current supplied to the plate having a conductive surface as well.

After the film formation, the plate having a conductive surface and the substrate were maintained to be close to each other, specifically have a distance of 2 mm, and thermal rising of the substrate in accordance with an elapsed time was examined. Note that a thermocouple was provided for a rear surface of the substrate, that is, a surface on which film formation is not to be performed, for the examination since the distance between plate and substrate was 2 mm which is narrow.

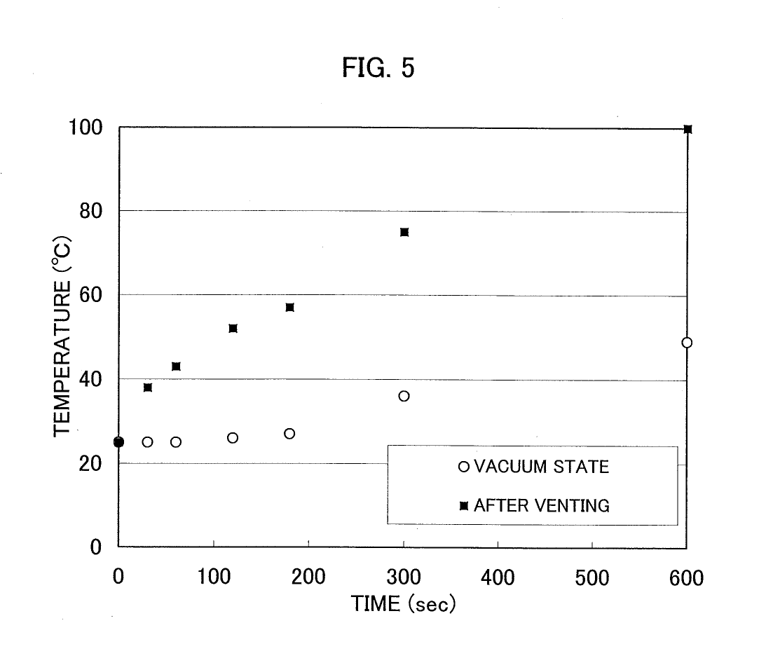

After the film formation, the thermal rising of the substrate in accordance with an elapsed time was examined and plotted while inside the film-formation chamber remained the vacuum state. A graph thereof is shown in FIG. 5. Further, also in FIG. 5, thermal rising of the substrate in accordance with an elapsed time was examined and plotted after a nitrogen gas was introduced into the film-formation chamber such that inside the formation chamber was made in the atmospheric pressure state after the film formation. Note that ‘venting’ refers to change of the vacuum state in the film-formation chamber to the atmospheric pressure state by introduction of an inert gas.

As shown in FIG. 5, when the vacuum state was kept, hardly any heat conduction took place and the rear-surface temperature of the substrate was just about 50° C. even after the substrate has been left for 10 minutes, nevertheless the distance between plate and substrate was only 2 mm.

Further, as shown in FIG. 5, when the plate and the substrate were left while keeping them to be close to each other after venting, residual heat of the plate was propagated to the substrate by convection of nitrogen or the like and the substrate temperature rose.

According to these, in the case where heating is to be intentionally performed after film formation, it is preferable to vent the film-formation chamber while the substrate and the plate are kept to be close to each other. By thus doing, need for separate heat treatment can be cut out and thermal energy can be used without waste.

To the contrary, in the case where heating of the substrate is to be suppressed, it is preferable to keep the substrate away from the plate after film formation so as not to heat the substrate and carry the substrate into the carrier chamber which is coupled to the film-formation chamber while keeping the vacuum state in the film-formation chamber.

On the present invention having the above-described structures, further specific description will be made with embodiments below.

### EMBODIMENT 1

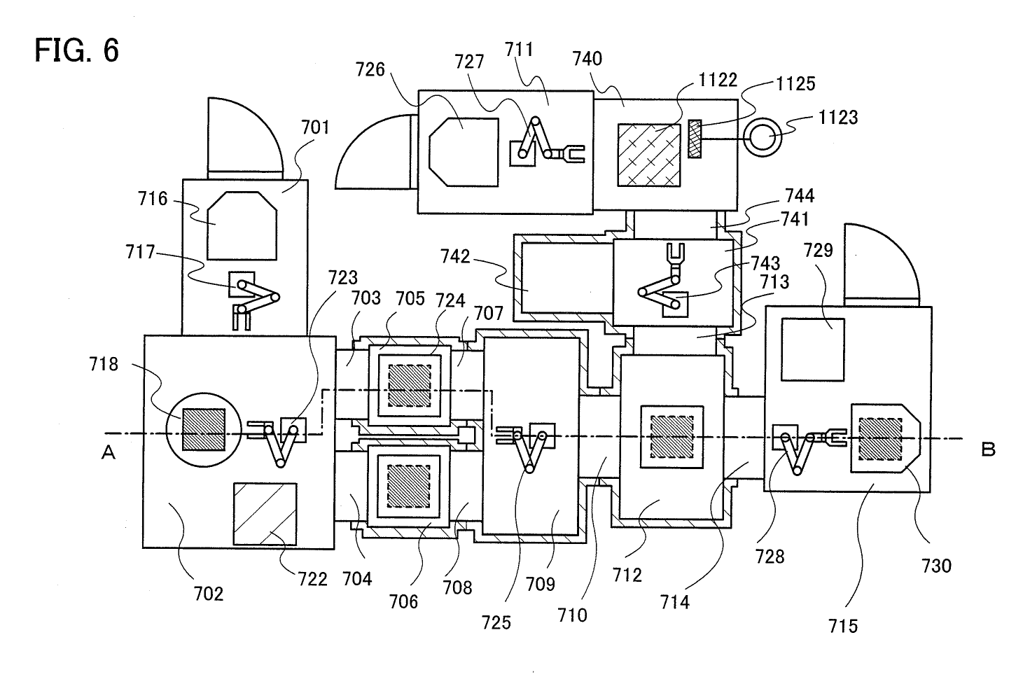

Size of a manufacturing apparatus can be reduced by the method for manufacturing a full-color display device of the present invention. In this embodiment, one example of a manufacturing apparatus for manufacturing a full-color display device is described using FIGS. 6, 7, and 8.

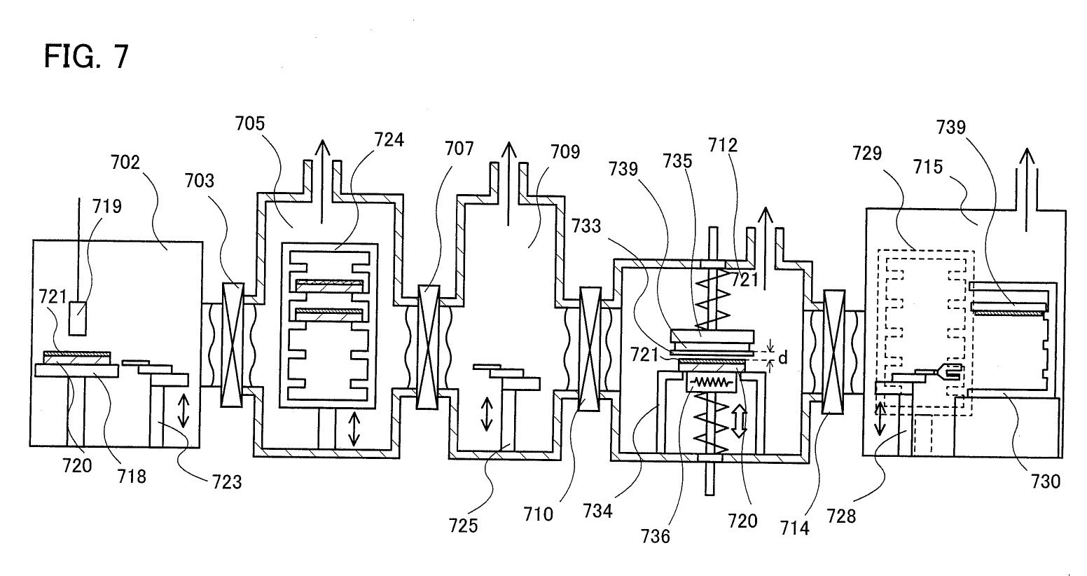

FIG. 6 is a top-plane view of a multi-chamber manufacturing apparatus, and FIG. 7 corresponds to a cross-sectional view taken along a dashed line A-B thereof.

First, an arrangement in the manufacturing apparatus is described using FIG. 6. A first load chamber 701 in which a first substrate (also called a plate) is set is coupled to a first film-formation chamber 702. The first film-formation chamber 702 is coupled to a first stock chamber 705 via a first gate valve 703, and to a second stock chamber 706 via a second gate valve 704. Further, the first stock chamber 705 is coupled to a carrier chamber 709 via a third gate valve 707. Further, the second stock chamber 706 is coupled to the carrier chamber 709 via a fourth gate valve 708.

In the first film-formation chamber 702, it is possible to form an environment of an atmosphere in which the amount of ozone is controlled as appropriate or an environment of a nitrogen atmosphere in which the oxygen density and the dew point are controlled. Further, a hot plate or an oven is included for performing drying or the like after application. Further, the first film-formation chamber 702 preferably has a function of surface cleaning or of improvement in wettability with a UV lamp or the like if needed. The first film-formation chamber 702 is a film-formation apparatus for film formation on the plate in the atmospheric pressure environment, and the first stock chamber 705 is a chamber to store the plate on which film formation has been performed in the atmospheric pressure environment and to deliver to a second film-formation chamber 712 that is evacuated to vacuum. In such a structure, evacuation to vacuum is needed each time after processing of the predetermined number of plates. That is, the period of time taken for venting or exhaust of the first stock chamber 705 directly affects throughput of the manufacturing apparatus. Thus, as shown in FIG. 6, two carrier courses are provided. By provision of the two carrier courses, a plurality of substrates can be processed efficiently so that process time per substrate can be reduced. For example, during the period in which the first stock chamber 705 is vented or exhausted, the plate on which film formation has been performed in the first film-formation chamber 702 can be stored in the second stock chamber 706. Note that the present invention is not limited to the two carrier courses and three or more carrier courses may be provided as well.

The carrier chamber 709 is coupled to the second film-formation chamber 712 via a fifth gate valve 710. Further, the second film-formation chamber 712 is coupled to an unload chamber 715 via a sixth gate valve 714. Further, a second load chamber 711 in which a second substrate is set is coupled to a third film-formation chamber 740, and the third film-formation chamber 740 is coupled to a carrier chamber 741 via a seventh gate valve 744. The carrier chamber 741 is coupled to the second film-formation chamber 712 via an eighth gate valve 713. The carrier chamber 741 is also coupled to a heating chamber 742.

Hereinafter, a procedure in which a plate that is the first substrate is carried into the manufacturing apparatus, and the second substrate provided in advance with a thin film transistor, an anode (a first electrode), and an insulator to cover an edge of the anode is carried into the manufacturing apparatus shown in FIG. 6 to manufacture a light-emitting device will be described.

First, the plate that is the first substrate is set in the first load chamber 701. The manufacturing apparatus is designed such that a cassette 716 storing a plurality of plates can be provided.

Then, the plate is carried onto a stage 718 in the first film-formation chamber 702 by a carrier robot 717. In the first film-formation chamber 702, a material layer is formed over the plate with an application apparatus using a spin-coating method. Note that the present invention is not limited to the application apparatus using a spin-coating method and an application apparatus using a spraying method, an ink jet method, or the like can be used. Further, the plate surface is subjected to UV treatment if necessary. Further, if baking is needed, a hot plate 722 is used. The state of the first film-formation chamber 702 can be seen in FIG. 7 which shows a cross section in which a material solution is dropped from a nozzle 719 and a material layer 721 is formed over a plate 720 disposed on the stage 718. In this embodiment, a material solution in which a light-emitting organic material is dispersed in a high polymer material is dropped and baked to form the material layer 721. A single layer of a light-emitting organic material which emits white light may be used as well. Alternatively, if a stacked layer is used for white light emission, three kinds of plates that are different material layers are prepared.

Then, the plate is carried into the first stock chamber 705 by a carrier robot 723 with the first gate valve 703 opened. After the plate is carried into the first stock chamber 705, the pressure in the first stock chamber 705 is reduced. As shown in FIG. 7, a structure in which a plurality of plates can be stored in the first stock chamber 705, that is, in this embodiment, a plate stock holder 724 capable of up-and-down movement is provided is preferable. Further, a mechanism capable of heating the plate in the first stock chamber may be provided. The first stock chamber 705 is coupled to a vacuum exhaust process chamber, and it is preferable that an inert gas be introduced to make the atmospheric pressure after vacuum exhaust is performed.

Then, after the pressure in the first stock chamber 705 is reduced, the plate is carried into the carrier chamber 709 with the third gate valve 707 opened and carried into the second film-formation chamber 712 with the fifth gate valve 710 opened. The carrier chamber 709 is coupled to a vacuum exhaust process chamber, and it is preferable that vacuum exhaust be performed in advance and the vacuum state be kept such that moisture or oxygen does not exists in the carrier chamber 709 as much as possible. The plate is carried with a carrier robot 725 provided in the carrier chamber 709.

Through the procedure so far, the plate provided with the material layer is set in the second film-formation chamber 712. This material layer becomes a second material layer to be formed over a first material layer provided over the second substrate at a later step.

Next, a procedure for setting a second substrate 739 which has been provided with the thin film transistor, the anode (first electrode), and the insulator covering an edge of the anode in the second film-formation chamber 712 will be described.

First, a cassette 726 in which a plurality of second substrates has been stored is set in the second load chamber 711 as shown in FIG. 6. The second load chamber 711 is coupled to the third film-formation chamber 740. Then the second substrate is carried into the third film-formation chamber 740 with a carrier robot 727. Further, when the second substrate 739 which has been provided with the thin film transistor is stored in the cassette 726, the second substrate 739 is preferably set to be in the face-down state so as not to attach dust to the first electrode as much as possible and a substrate reversal mechanism is preferably provided for the carrier robot 727. The second substrate is provided in the face-up state on a stage 1122 in the third film-formation chamber 740.

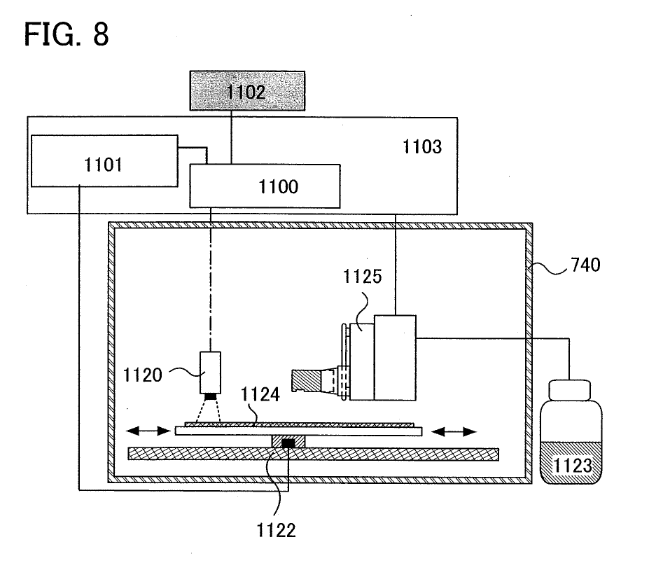

One example of a cross section of the third film-formation chamber 740 is shown in FIG. 8. A droplet discharge apparatus is provided in the third film-formation chamber 740. The droplet discharge apparatus includes a droplet discharge means 1125 provided with a head with a plurality of nozzles arranged in one axial direction, a control portion 1103 for controlling the droplet discharge means 1125, the stage 1122 that fixes a substrate 1124 and moves in X, Y, and θ directions, and the like. This stage 1122 also has a function for fixing the substrate 1124 by a technique such as vacuum chuck. A composition is discharged to the substrate 1124 from a discharging outlet of each nozzle included in the droplet discharge means 1125 so that a pattern is formed.

The stage 1122 and the droplet discharge means 1125 are controlled by the control portion 1103. The control portion 1103 includes a stage position control portion 1101. An imaging means 1120 such as a CCD camera is also controlled by the control portion 1103. The imaging means 1120 detects the position of a marker, and supplies the detected information to the control portion 1103. Further, the detected information can also be displayed on a monitor 1102. Furthermore, the control portion 1103 includes an alignment position control portion 1100. The composition is supplied from an ink bottle 1123 to the droplet discharge means 1125.

Note that, in forming the pattern, the droplet discharge means 1125 may be moved, or the stage 1122 may be moved with the droplet discharge means 1125 fixed. In the case where the droplet discharge means 1125 is moved, however, acceleration of the composition, the distance between the nozzles provided for the droplet discharge means 1125 and an object to be processed, and the environment need to be considered.

Furthermore, although not shown, a movement mechanism in which the head moves up and down, a control means thereof, and/or the like may be provided as an accompanying structure in order to improve the accuracy of landing of the discharged component. By doing so, the distance between the head and the substrate 1124 can be varied depending on the properties of the composition to be discharged. Furthermore, a gas supply means and a shower head may be provided. By doing so, the atmosphere can be substituted for an atmosphere of the same gas as a solvent of the composition so that desiccation can be prevented to some extent. Further, a clean unit or the like for supplying clean air to reduce dust in a work area may be provided. Further, although not shown, a means for measuring various values of physical properties such as temperature, pressure, and the like may be provided as well as a manufacturing apparatus for heating a substrate, as necessary. These means can be collectively controlled by the control means provided outside a chassis. Furthermore, if the control means is connected to a manufacturing management system or the like through an LAN cable, a wireless LAN, an optical fiber, or the like, the process can be uniformly managed from the outside, which leads to improvement in productivity. Note that vacuum exhaust may be performed on the third film-formation chamber 740 and the droplet discharge apparatus may be operated in a reduced pressure in order to hasten desiccation of the landed composition and to remove a solvent component of the composition.

In this embodiment, first material layers having different thicknesses are formed in a region for red-light-emitting element, a region for green-light-emitting element, and a region for blue-light-emitting element, respectively. Each of the first material layers is a layer in which an organic compound and a metal oxide which is an inorganic compound are mixed. The metal oxide is at least one kind of molybdenum oxide, vanadium oxide, and rhenium oxide. The ink jet device shown in FIG. 8 can control film thickness precisely by adjustment of a minute amount of a droplet. By adjusting the thickness of the first material layer of each light-emitting element, which is different depending on an emission color, a blue light emission component, a green light emission component, or a red light emission component among a white light emission component can be selectively emphasized and taken out by light interference phenomenon.

As shown in FIG. 6, the second substrate over which the first material layer has been formed is carried into the carrier chamber 741 by a carrier robot 743 with the seventh gate valve 744 opened. The carrier chamber 741 is coupled to a vacuum exhaust process chamber in order to reduce moisture in the chamber, and it is preferable that an inert gas be introduced to make the atmospheric pressure after vacuum exhaust is performed. Vacuum exhaust in the carrier chamber 741 provided with the carrier robot 743 is performed, and then the second substrate is carried into the second film-formation chamber 712 by the carrier robot 743 with the eighth gate valve 713 opened. Further, a substrate reversal mechanism is preferably provided for the carrier robot 743. In this embodiment, the second substrate 739 is disposed in the face-down state in the second film-formation chamber 712.

Further, baking of the first material layer can be performed by heat treatment or the like in the third film-formation chamber 740; however, in the case where vacuum heating is to be performed in order to remove moisture of the second substrate, vacuum heating may be performed in the heating chamber 742 coupled to the carrier chamber 741 as well. It is preferable that the heating chamber 742 be coupled to a vacuum exhaust process chamber and have a structure such that a plurality of second substrates can be stored and heated at the same time.

Through the procedure so far, the plate 720 and the second substrate 739 are set in the second film-formation chamber 712 as shown in FIG. 7.

In the second film-formation chamber 712, at least a plate supporting base 734 which is a first substrate supporting means, a second substrate supporting base 735 which is a second substrate supporting means, and a heater capable of up-and-down movement as a heat source 736 are included. Further, a mask 733 for selective film formation is disposed so as to overlap the second substrate 739. It is preferable that the mask 733 and the second substrate 739 be aligned in advance.

Further, the surface over which the second material layer 721 has been formed of the plate 720 and a surface over which a film is to be formed of the second substrate 739 are fixed to the substrate supporting mechanism so as to face each other. Then, the second substrate supporting base 735 is moved until the distance between the second material layer 721 and the second substrate 739 is reduced to d. The distance d is set to less than or equal to 100 mm, and preferably less than or equal to 5 mm. Note that, since the second substrate 739 is a glass substrate, the lower limit of the distance d is 0.5 mm in consideration of distortion or deflection thereof. In this embodiment, the distance d is set to 5 mm since the mask is interposed therebetween. The distance d is determined so that at least the mask 733 and the second substrate 739 are not in contact with each other. The smaller the distance d is, the more expansion in a vapor-deposition direction can be suppressed so that evaporation entering around the mask can be suppressed.

Then, as shown in FIG. 7, the heat source 736 is approached to the plate 720 while keeping the distance d. A heater capable of up-and-down movement under the plate is used as the heat source 736. Although the heater is basically set to be constant at a predetermined temperature, the temperature may be controlled so that the temperature is raised or lowered in the range in which the takt time is not affected.

When the heat source 736 is approached to the plate 720, the second material layer 721 over the plate is heated and evaporated in a short period of time by direct heat conduction, so that film formation of a vapor-deposition material is performed on the surface over which a film is to be formed (i.e., a bottom surface) of the second substrate 739 which is disposed to face the second material layer 721. Note that, in this embodiment, the light-emitting organic compound dispersed into the second material layer 721 is evaporated to form a film over the first material layer of the second substrate 739, and the high polymer material is left over the plate. The film is selectively formed only in a region which passes an opening of the mask 733. Further, film thickness uniformity of the film formation on the bottom surface of the second substrate 739 can be set to less than 3%.

Accordingly, the first material layer (layer in which an organic compound and a metal oxide which is an inorganic compound are mixed) and the second material layer (light-emitting layer) can be stacked over the anode (first electrode) over the second substrate. Further, after the light-emitting layer is formed, an electron transport layer or an electron injection layer may be formed in the second film-formation chamber and stacked. Further, after the light-emitting layer is formed, the cathode (second electrode) may be formed in the second film-formation chamber 712 and stacked.

Through the above-described process, the red-light-emitting element, blue-light-emitting element, and green-light-emitting element can be formed over the second substrate.

As shown in FIGS. 6 and 7, after film formation on the second substrate 739 is completed, the second substrate 739 is carried into the unload chamber 715 with the sixth gate valve 714 opened. The unload chamber 715 is also coupled to a vacuum exhaust process chamber and inside the unload chamber is made in a reduced pressure state at the time of carrying the second substrate 739. The second substrate 739 is stored in a cassette 730 by a carrier robot 728. Note that the second substrate 739 is set in the cassette 730 so that the surface on which film formation has been performed faces downward to prevent attachment of impurities such as dust. As long as the plate 720 has the same size and thickness as the second substrate 739, the plate 720 can also be stored in the cassette 730 by the carrier robot 728. Further, a mask stock holder 729 may be provided in the unload chamber 715. By provision of the mask stock holder 729, a plurality of masks can be stored.

Further, a sealing chamber for sealing a light-emitting element may be coupled to the unload chamber 715. The sealing chamber is coupled to a load chamber for carrying a sealing can or a sealing substrate, and the second substrate and the sealing substrate are attached to each other in the sealing chamber. At that time, a substrate reversal mechanism is preferably provided for the carrier robot 728 if it is preferable to reverse the second substrate.

A magnetic levitation turbo molecular pump, a cryopump, or a dry pump is provided for the above-described vacuum exhaust process chamber. Accordingly, the ultimate degree of vacuum of the carrier chamber coupled to a feed chamber can be set to 10⁻⁵ to 10⁻⁶ Pa, and reverse diffusion of impurities from the pump side and the exhaust system can be further suppressed. An inert gas such as nitrogen or a rare gas is used as a gas to be introduced in order to prevent the impurities from being introduced into the apparatus. As the gas to be introduced into the apparatus, a gas that is highly purified by a gas refiner before the introduction into the apparatus is used. Thus, a gas refiner needs to be provided so that a gas is introduced into the vapor-deposition apparatus after it is highly purified. Accordingly, oxygen, moisture, or other impurities in the gas can be removed in advance, whereby these impurities can be prevented from being introduced into the apparatus.

Although the carrier robot is given as an example of a carrier means for the substrate or the plate, there is no particular limitation on the carrier means and a roller or the like may be used as well. Further, the position where each carrier robot is provided is not particularly limited to the arrangement in FIG. 6 and FIG. 7 and may be set to a desired position as appropriate.

In the manufacturing apparatus of this embodiment, scattering of a material in a vacuum chamber can be suppressed by reducing the distance between the film-formation substrate and the plate to be less than or equal to 100 mm, and preferably less than or equal to 5 mm. Thus, the interval of maintenance such as cleaning in the film-formation chamber can be lengthened. Furthermore, in the manufacturing apparatus of this embodiment, the first film-formation chamber 702 and the second film-formation chamber 712 are a face-up film-formation apparatus and a face-down system, respectively; accordingly, smooth film-formation processing can be performed without reversing the plate or the film-formation substrate in the middle of carrying the substrate.

In a multi-chamber manufacturing apparatus, there is no particular limitation on the arrangement of the film-formation chambers shown in FIGS. 6 and 7 as long as at least each one of the second film-formation chamber 712 and the third formation chamber 740 is provided. For example, a film-formation chamber in which a known film-formation method such as a vapor-deposition method with resistance heating or an EB evaporation method is used may be provided to be coupled to the second film-formation chamber 712.

The second film-formation chamber 712 is a so-called face-down film-formation chamber in which the surface over which a film is to be formed of the film-formation substrate is placed to be a bottom surface, but may be a face-up film-formation chamber as well. In a conventional vapor-deposition apparatus, it is difficult to adapt a face-up film-formation apparatus since a powdery vapor-deposition material is stored in a crucible or a vapor-deposition boat.

Further, the second film-formation chamber 712 can be remodeled to be a so-called substrate-vertically-disposed film-formation apparatus, which has a structure in which the surface over which a film is to be formed of the film-formation substrate is vertically set up with respect to the horizontal surface, as well. Further, the surface over which a film is to be formed of the film-formation substrate is not limited to be vertical with respect to the horizontal surface but may be slanted off the horizontal surface as well. In the case of a large-area substrate which is easily deflected, vertical set up of the surface of the film-formation substrate is preferable since the deflection of the film-formation substrate (and the mask) can be reduced.

Further, in the case where the second film-formation chamber 712 is the substrate-vertically-disposed film-formation apparatus, a mechanism of setting up the surface of the plate to be vertical to the horizontal surface in the middle of carrying the plate from the first film-formation chamber 702 to the second film-formation chamber 712 is provided. Further, a mechanism of setting up the film-formation substrate to be vertical to the horizontal surface in the middle of carrying the substrate from the second load chamber 711 to the second film-formation chamber 712 is provided.

That is, there is no particular limitation on the direction of the film-formation substrate in the second film-formation chamber 712, and as long as the film-formation substrate and the plate can be disposed at a distance of less than or equal to 100 mm, and preferably less than or equal to 5 mm, the film-formation apparatus can drastically improve the use efficiency of a vapor-deposition material and throughput.

Further, although the example of the multi-chamber manufacturing apparatus in which the second film-formation chamber 712 is provided as one chamber is described in this embodiment, there is no particular limitation on the present invention and it is needless to say that the second film-formation chamber 712 can be provided as one chamber in an in-line manufacturing apparatus as well.

Note that the film-formation method described in Embodiment Mode 1 can be implemented with the manufacturing apparatus described in this embodiment.

Further, the film-formation apparatus having a cleaning function described in Embodiment Mode 2 may be used as one of the chambers of the manufacturing apparatus described in this embodiment.

### EMBODIMENT 2

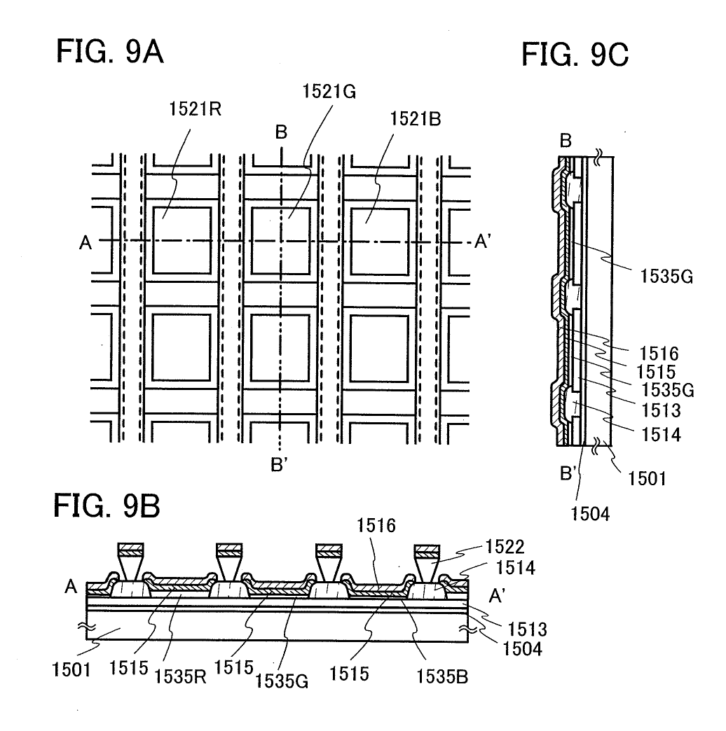

In this embodiment, an example of manufacturing a passive matrix light-emitting device over a glass substrate will be described using FIGS. 9A to 9C, 10, and 11.

In a passive matrix (simple matrix) light-emitting device, a plurality of anodes arranged in parallel and stripes (strip form) are provided perpendicularly to a plurality of cathodes arranged in parallel and stripes. A light-emitting layer or a fluorescent layer is interposed at each intersection between the anodes and the cathodes. Therefore, a pixel at an intersection of a selected anode (to which a voltage is applied) and a selected cathode emits light.

FIG. 9A is a top-plane view of a pixel portion before sealing. FIG. 9B is a cross-sectional view taken along a dashed line A-A′ in FIG. 9A. FIG. 9C is a cross-sectional view taken along a dashed line B-B′ in FIG. 9A.

An insulating film 1504 is formed over a first substrate 1501 as a base film. Note that the base film is not necessarily formed if not necessary. A plurality of first electrodes 1513 are arranged in stripes at constant intervals over the insulating film 1504. A stacked layer of a reflective thin metal film and a transparent conductive film is used as the first electrode 1513. Note that it is preferable that the first electrode 1513 can transmit part of light emission and reflect part of light emission in order to use a microcavity effect. A bank 1514 having openings each corresponding to a pixel is provided over the first electrodes 1513. The bank 1514 having openings is formed of an insulating material (a photosensitive or nonphotosensitive organic material such as polyimide, acrylic, polyamide, polyimide amide, resist, or benzocyclobutene, or an SOG film such as a SiOₓ film containing an alkyl group). Note that the openings corresponding to the pixels become red-light-emitting regions 1521R, green-light-emitting regions 1521G, and blue-light-emitting regions 1521B.

A plurality of inversely tapered banks 1522 which are parallel to each other and intersect with the first electrodes 1513 are provided over the banks 1514 having openings. The inversely tapered banks 1522 are formed by a photolithography method using a positive-type photosensitive resin by which a portion unexposed to light remains as a pattern, in which the amount of light exposure or the length of development time is adjusted so that a lower portion of the pattern is etched more.

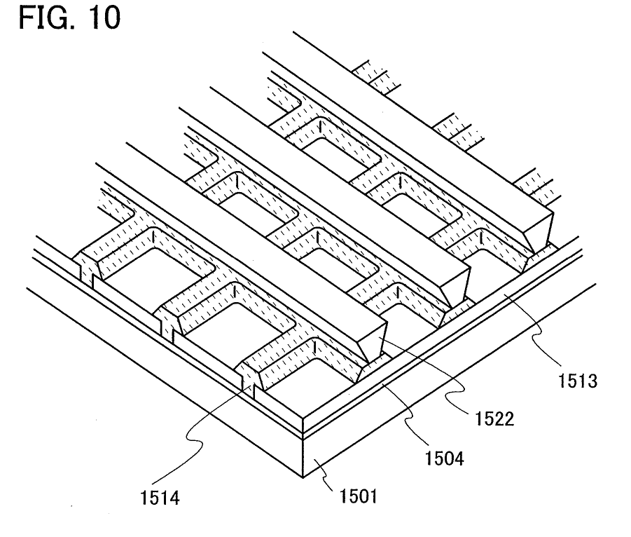

FIG. 10 is a perspective view immediately after formation of the plurality of inversely tapered banks 1522 which are parallel to each other. Note that the same reference numerals are used to denote the same portions as FIGS. 9A to 9C.

The thickness of each of the inversely tapered banks 1522 is set to be larger than the total thickness of a stacked-layer film including a light-emitting layer and a conductive film. On a first substrate having the structure shown in FIG. 10, formation of first material layers 1535R, 1535, and 1535B having different thicknesses is performed by an ink jet method. Specifically, the first material layers are formed in the third film-formation chamber 740 described in Embodiment 1. Each of the first material layers is a layer in which an organic compound and a metal oxide which is an inorganic compound are mixed. The metal oxide contained in each of the first material layers 1535R, 1535G, and 1535B is at least one kind of molybdenum oxide, vanadium oxide, and rhenium oxide.

Then, a second material layer 1515 is formed. The second material layer 1515 includes at least a single layer of white light emission or a stacked layer of white light emission obtained by synthesis (e.g., a staked layer of a red-light-emitting layer, a green-light-emitting layer, and a blue-light-emitting layer). The thickness of the first material layers 1535R, 1535G, and 1535B in the plural kinds of light-emitting elements is different depending on an emission color such that a desired emission color is obtained. By adjusting the thickness of the first material layer of each light-emitting element, which is different depending on an emission color, a blue light emission component, a green light emission component, or a red light emission component among a plurality of components for white light emission can be selectively emphasized and taken out by light interference phenomenon. In this embodiment, an example in which the thickness of the first material layer is varied to form a light-emitting device capable of full-color display, from which three kinds (R, G, and B) of light emission can be obtained is described. The first material layers 1535R, 1535G, and 1535B are formed into stripes parallel to each other.

Specifically, film formation of the second material layer 1515 is performed in the second film-formation chamber 712 described in Embodiment 1. A plate over which the second material layer has been formed is prepared and carried into the second film-formation chamber described in Embodiment 1. Then, the substrate over which the first electrodes 1513 have been provided is also carried into the second film-formation chamber. Then, a surface of the plate is heated by a heat source with the same area as or a larger area than the substrate, whereby vapor deposition is performed.

Furthermore, a reflective conductive film that becomes a second electrode is formed to be stacked, so that separation into a plurality of regions that are electrically isolated from each other is performed as shown in FIGS. 9A to 9C and the second material layers 1515 each including a light-emitting layer and second electrodes 1516 are formed. The second electrodes 1516 are electrodes arranged in stripe form that are parallel to each other and extend along a direction intersecting with the first electrodes 1513. Note that the second material layer and the conductive film are also formed over each of the inversely tapered banks 1522; however, they are electrically insulated from the second material layers 1515 and the second electrodes 1516.

Alternatively, a stacked-layer film including a light-emitting layer which emits light of the same color may be formed over the entire surface to provide single-color-light-emitting elements, so that a light-emitting device capable of performing monochromatic display or a light-emitting device capable of performing area color display may be provided. Further, a light-emitting device capable of performing full color display may be formed by combining color filters with a light-emitting device which provides white light emission as well.

Further, sealing is performed with a sealant such as a sealant can or a glass substrate for sealing if necessary. In this embodiment, a glass substrate is used as the second substrate, and the first substrate and the second substrate are attached to each other with an adhesive material such as a sealing material to seal a space surrounded by the adhesive material such as a sealing material. The space that is sealed is filled with a filler or a dried inert gas. Furthermore, a space between the first substrate and the filler may be filled and sealed with a desiccant or the like in order to improve reliability of the light-emitting device. The desiccant removes a minute amount of moisture, thereby achieving sufficient desiccation. As the desiccant, a substance that adsorbs moisture by chemical adsorption such as oxide of alkaline earth metal such as calcium oxide or barium oxide can be used. Note that a substance that adsorbs moisture by physical adsorption such as zeolite or silicagel may be used as the desiccant as well.

However, if the sealant that covers and is in contact with the light-emitting element is provided to sufficiently block the outside air, the desiccant is not necessarily provided.

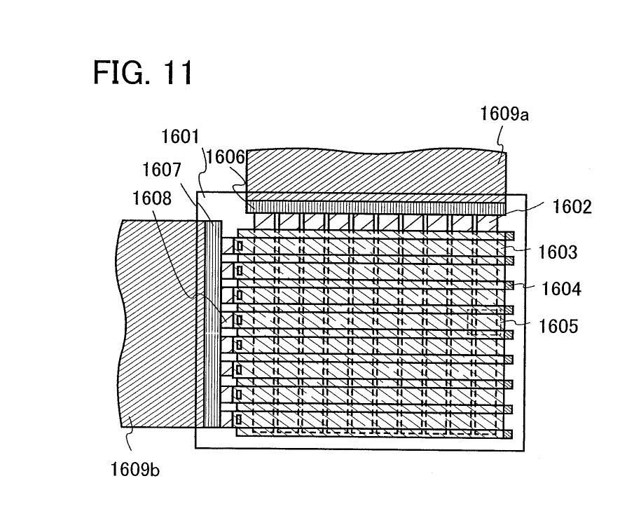

Next, a top-plane view of a light-emitting module mounted with an FPC or the like is shown in FIG. 11.

Note that the light-emitting device in this specification refers to an image display device, a light emission device, or a light source (including a lighting device). Further, the light-emitting device includes the following modules in its category: a module in which a connector such as a flexible printed circuit (FPC), a tape automated bonding (TAB) tape, or a tape carrier package (TCP) has been attached to a light-emitting device; a module in which a printed wiring board has been provided at the end of a TAB tape or a TCP; and a module in which an integrated circuit (IC) has been directly mounted over a light-emitting device by a chip on glass (COG) method.

As shown in FIG. 11, in a pixel portion for displaying an image over a substrate 1601, scanning lines and data lines intersect with each other perpendicularly.

The first electrodes 1513 in FIGS. 9A to 9C correspond to scanning lines 1603 in FIG. 11, the second electrodes 1516 correspond to data lines 1602, and the inversely tapered banks 1522 correspond to banks 1604. A light-emitting layer is interposed between the data line 1602 and the scanning line 1603, and an intersection portion denoted by a region 1605 corresponds to one pixel.

Note that the scanning lines 1603 are electrically connected to connection wires 1608 at the ends thereof, and the connection wires 1608 are connected to an FPC 1609b via an input terminal 1607. The data lines 1602 are connected to an FPC 1609a via an input terminal 1606.

Further, if necessary, a polarizing plate, a circularly polarizing plate (including an elliptically polarizing plate), a retardation plate (a quarter-wave plate or a half-wave plate), or an optical film such as a color filter may be provided over a light exit surface as appropriate. Further, an anti-reflection film may be provided for the polarizing plate or the circularly polarizing plate. For example, anti-glare treatment may be carried out by which reflected light can be scattered by roughness of a surface so as to reduce reflection.

Through the above-described process, a flexible passive-matrix light-emitting device capable of performing full-color display can be manufactured. With the manufacturing apparatus shown in FIG. 4 or 6, the period of time taken for the manufacturing process of a full-color display device can be reduced.

Further, although the example in which a driver circuit is not provided over a substrate is shown in FIG. 11, an IC chip having a driver circuit may be mounted as described below.

In the case where the IC chip is mounted, a data line side IC and a scanning line side IC, in each of which a driver circuit for transmitting a signal to a pixel portion is formed, are mounted on the periphery of (outside) the pixel portion by a COG method. The mounting may be performed by a TCP or a wire bonding method other than the COG method as well. The TCP is a TAB tape mounted with an IC, and the TAB tape is connected to a wire over an element formation substrate so that the IC is mounted. Each of the data line side IC and the scanning line side IC may be formed using a silicon substrate, or may be formed by forming a driver circuit of a TFT over a glass substrate, a quartz substrate, or a plastic substrate. Further, although the example in which one IC is provided on one side is described in this embodiment, a plurality of ICs which have been divided from each other may be provided on one side as well.

### EMBODIMENT 3

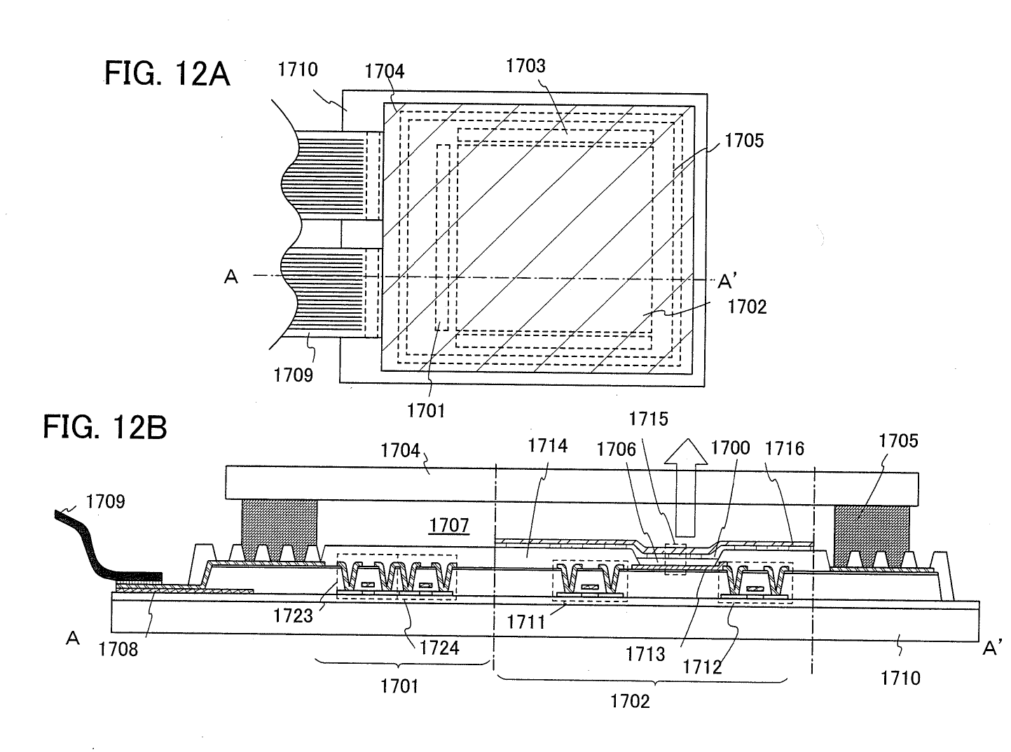

In this embodiment, a light-emitting device formed with the manufacturing apparatus shown in FIG. 6 or 4 will be described using FIGS. 12A and 12B. Note that FIG. 12A is a top-plane view showing the light-emitting device and FIG. 12B is a cross-sectional view taken along a line A-A′ in FIG. 12A. Reference numeral 1701 indicated by a dotted line denotes a driver circuit portion (a source side driver circuit); 1702 denotes a pixel portion; 1703 denotes a driver circuit portion (a gate side driver circuit); 1704 denotes a sealing substrate; 1705 denotes a sealant; and 1707 which is a space surrounded by the sealant 1705 denotes a space filled with a transparent resin.

Reference numeral 1708 denotes a wire for transmitting signals input to the source side driver circuit 1701 and the gate side driver circuit 1703, and the wire 1708 receives a video signal, a clock signal, a start signal, a reset signal, and the like from a flexible printed circuit (FPC) 1709 which is an external input terminal. Note that, although only the FPC is shown, a printed wiring board (PWB) may be attached to the FPC. The light-emitting device in this specification includes, in its category, not only the light-emitting device itself but also the light-emitting device provided with an FPC and/or a PWB.

Next, a cross-sectional structure thereof will be described using FIG. 12B. A driver circuit portion and a pixel portion are formed over an element substrate 1710; the source side driver circuit 1701 that is one driver circuit portion and the pixel portion 1702 are shown in FIG. 12B.

Note that, for the source side driver circuit 1701, a CMOS circuit in which an n-channel TFT 1723 and a p-channel TFT 1724 are combined is formed. Further, a circuit included in the driver circuit may be a known CMOS circuit, PMOS circuit, or NMOS circuit. Further, although a driver-integrated type in which a driver circuit is formed over a substrate is described in this embodiment, the present invention is not limited to this type and a driver circuit may be formed not over a substrate but outside the substrate as well.

Further, the pixel portion 1702 is formed of a plurality of pixels each including a switching TFT 1711, a current control TFT 1712, and an anode 1713 that is electrically connected to a drain of the current control TFT 1712. An insulator 1714 is formed so as to cover an edge of the anode 1713. In this embodiment, the insulator 1714 is formed of a positive type photosensitive acrylic resin film.

Further, the insulator 1714 is formed so as to have a curved surface having curvature at an upper or lower edge portion thereof in order to provide favorable film coverage. For example, in the case where a positive type photosensitive acrylic is used as a material for the insulator 1714, the upper edge portion of the insulator 1714 has preferably a curved surface having a radius of curvature (0.2 to 3 μm). Further, for the insulator 1714, either a negative type that becomes insoluble in an etchant by photosensitive light or a positive type that becomes soluble in an etchant by light can be used, and an inorganic compound such as silicon oxide or silicon oxynitride can be used as well as an organic compound.

A first material layer 1706, a layer containing an organic material 1700, and a cathode 1716 are formed over the anode 1713. Here, as a material used for the anode 1713, a reflective material having a high work function is preferable. For example, a single layer film such as a tungsten film, a Zn film, or a Pt film can be used. Further, a stacked-layer structure may be employed as well; for example, a stacked layer of a titanium nitride film and a film containing aluminum as the main component or a three-layer structure of a titanium nitride film, a film containing aluminum as the main component, and a titanium nitride film can be used. Further, a stacked layer of a transparent conductive film such as an indium tin oxide (ITO) film, an indium tin silicon oxide (ITSO) film, or an indium zinc oxide (IZO) film and a reflective metal film may be used as well.

Further, a light-emitting element 1715 has a structure in which the anode 1713, the first material layer 1706, the layer containing an organic material 1700, and the cathode 1716 are stacked; specifically, a hole injection layer, a hole transport layer, a light-emitting layer, an electron transport layer, an electron injection layer, and/or the like are stacked as appropriate. The first material layer 1706 is formed to the thickness which is varied depending on each of the red-light-emitting region, blue-light-emitting region, and a green-light-emitting region. Specifically, the first material layer 1706 is formed selectively with the third film-formation chamber 740 described in Embodiment 1. In addition, the layer containing an organic compound 1700 is formed in the second film-formation chamber 712. Further, since the film thickness uniformity is excellent which is less than 3% with the second film-formation chamber 712 described in Embodiment 1, a desired film thickness can be obtained, whereby luminance variations in a light-emitting device can be reduced.

As the cathode 1716, a stacked layer of a thin metal film with a small thickness and a transparent conductive film (e.g., a film of oxide indium-tin oxide (ITO), indium tin silicon oxide (ITSO), indium oxide-zinc oxide (In₂O₃—ZnO), or zinc oxide (ZnO)) is used.

Furthermore, the structure in which the light-emitting element 1715 is provided in the space 1707 surrounded by the element substrate 1710, the sealing substrate 1704, and the sealant 1705 is obtained by attaching the light-transmitting sealing substrate 1704 to the element substrate 1710 with the sealant 1705. Note that the space 1707 is filled with a light-transmitting sealant.

Note that an epoxy-based resin is preferably used for the sealant 1705. In addition, it is preferable that such a material do not transmit moisture or oxygen as much as possible. Further, as a material used for the sealing substrate 1704, a plastic substrate made of fiberglass-reinforced plastics (FRP), polyvinyl fluoride (PVF), polyester, acrylic, or the like can be used as well as a glass substrate or a quartz substrate.

Through the above, the light-emitting device including a light-emitting element of the present invention can be obtained. Manufacturing cost per substrate tends to increase in the case of an active matrix light-emitting device because of manufacture of a TFT; however, by using a large-area substrate with the manufacturing apparatus described in Embodiment 1, film-formation process time per substrate can be largely shortened so that a large reduction in cost for each light-emitting device can be achieved. Therefore, the manufacturing apparatus described in Embodiment 1 is useful as a manufacturing apparatus for an active matrix light-emitting device.

Note that the light-emitting device described in this embodiment can be implemented freely combining with any of Embodiment Mode 1 and Embodiment Mode 2.

### EMBODIMENT 4

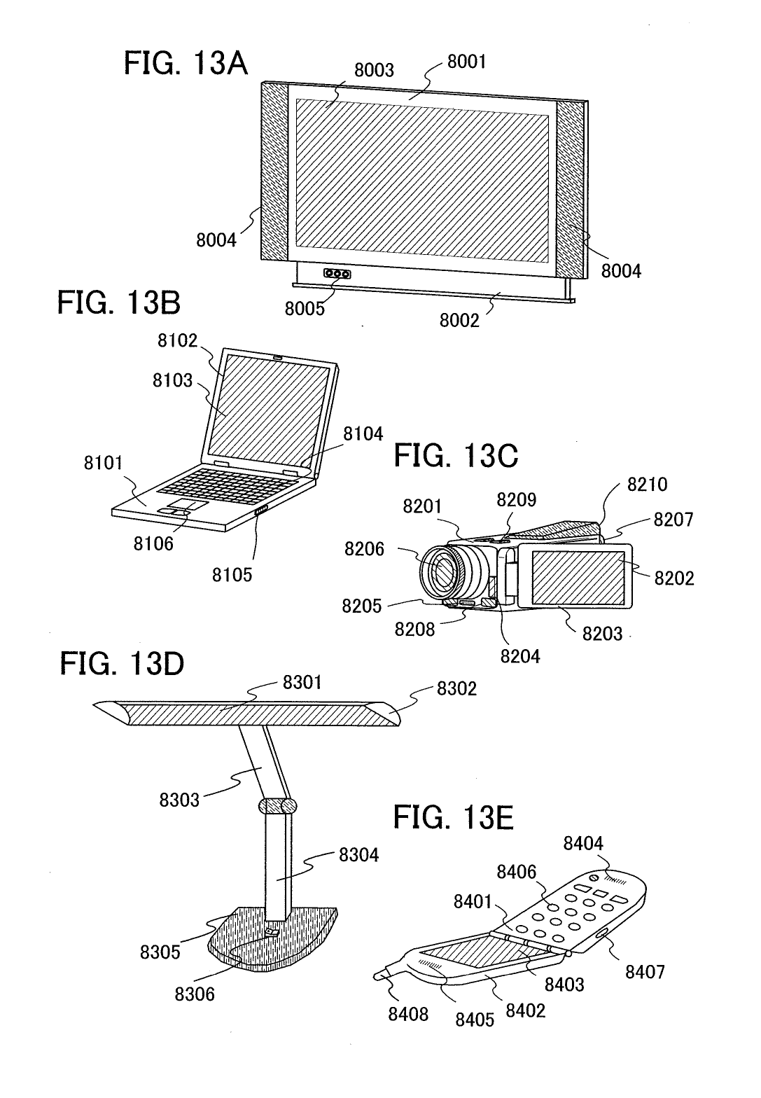

In this embodiment, explanation will be made using FIGS. 13A to 13E on various electronic appliances manufactured using a light-emitting device including a light-emitting element manufactured by the manufacturing method of the present invention.

Examples of the electronic appliances manufactured using the film-formation apparatus of the present invention include: televisions, cameras such as video cameras or digital cameras, goggle displays (head mount displays), navigation systems, audio reproducing devices (e.g., car audio component stereos and audio component stereos), notebook personal computers, game machines, portable information terminals (e.g., mobile computers, mobile phones, portable game machines, and electronic books), and image reproducing devices provided with recording media (specifically, devices that can reproduce a recording medium such as a digital versatile disc (DVD) and is provided with a display device capable of displaying the reproduced images), lighting appliances, and the like. Specific examples of these electronic appliances are illustrated in FIGS. 13A to 13E.

FIG. 13A illustrates a display device including a chassis 8001, a supporting base 8002, a display portion 8003, a speaker portion 8004, a video input terminal 8005, and the like. The display device is manufactured by using a light-emitting device manufactured using the present invention for the display portion 8003. Note that the display device includes in its category any device for displaying information, for example, for a personal computer, for receiving TV broadcasting, or for displaying an advertisement. The manufacturing apparatus having a cleaning function of the present invention enables large reduction in manufacturing cost so that an inexpensive display device can be provided.

FIG. 13B illustrates a notebook personal computer including a main body 8101, a chassis 8102, a display portion 8103, a keyboard 8104, an external connection port 8105, a pointing device 8106, and the like. The notebook personal computer is manufactured by using, for the display portion 8103, a light-emitting device including a light-emitting element formed by the manufacturing method of the present invention. The manufacturing apparatus having a cleaning function of the present invention enables large reduction in manufacturing cost so that an inexpensive notebook personal computer can be provided.

FIG. 13C illustrates a video camera including a main body 8201, a display portion 8202, a chassis 8203, an external connection port 8204, a remote control receiving portion 8205, an image receiving portion 8206, a battery 8207, an audio input portion 8208, operation keys 8209, an eyepiece portion 8210, and the like. The video camera is manufactured by using, for the display portion 8202, a light-emitting device including a light-emitting element formed by the manufacturing method of the present invention. The manufacturing apparatus having a cleaning function of the present invention enables large reduction in manufacturing cost so that an inexpensive video camera can be provided.

FIG. 15D illustrates a desktop lighting appliance including a lighting portion 8301, a shade 8302, an adjustable arm 8303, a support 8304, a base 8305, and a power source 8306. The desk lighting appliance is manufactured by using, for the lighting portion 8301, a light-emitting device formed with the film-formation apparatus of the present invention. Note that the lighting appliance includes, in its category, a ceiling-fixed lighting appliance, a wall-hanging lighting appliance, and the like. The manufacturing apparatus having a cleaning function of the present invention enables large reduction in manufacturing cost so that an inexpensive desktop lighting appliance can be provided.

FIG. 13E illustrates a mobile phone including a main body 8401, a chassis 8402, a display portion 8403, an audio input portion 8404, an audio output portion 8405, operation keys 8406, an external connection port 8407, an antenna 8408, and the like. The mobile phone is manufactured by using, for the display portion 8403, a light-emitting device including a light-emitting element formed by the film-formation apparatus of the present invention. The manufacturing apparatus having a cleaning function of the present invention enables large reduction in manufacturing cost so that an inexpensive mobile phone can be provided.

As described above, an electronic appliance or a lighting appliance using a light-emitting element formed by the manufacturing method of present invention can be obtained. The applicable range of a light-emitting device including a light-emitting element formed by the manufacturing method of the present invention is so wide that the light-emitting device can be applied to electronic appliances in various fields.

Note that the light-emitting device described in this embodiment can be implemented freely combining with any of the manufacturing method described in Embodiment Mode 1, the film-formation apparatus and the manufacturing apparatus having a cleaning function described in Embodiment Mode 2, and the manufacturing apparatus described in Embodiment 1. Furthermore, the light-emitting device described in this embodiment can be implemented freely combining with any of Embodiments 2 and 3.

This application is based on Japanese Patent Application Serial No. 2007-075433 filed with Japan Patent Office on Mar. 22, 2007, the entire contents of which are hereby incorporated by reference.

What is claimed is:

1. A method for manufacturing a light-emitting device, the light-emitting device having at least a first light emitting element emitting a first color and a second light emitting element emitting a second color different from the first color, comprising steps of:
forming a first electrode over a first substrate;
forming selectively a first material layer over the first electrode by a droplet discharge method;
forming a layer containing a light-emitting material over a second substrate;
disposing the layer containing the light-emitting material formed over the second substrate and the first material layer formed over the first substrate so as to face each other;
heating the second substrate and vaporizing the layer containing the light-emitting material so that a second material layer containing the light-emitting material and emitting white light is formed over the first material layer; and
forming a second electrode over the second material layer,
wherein the first material layers of the first and second light-emitting elements have different film thicknesses, respectively.

2. The method for manufacturing the light-emitting device, according to claim 1, wherein the light-emitting device comprises a red-light-emitting element, a blue-light-emitting element, and a green-light-emitting element.

3. The method for manufacturing the light-emitting device, according to claim 1, wherein a distance between the first and second substrates is in a range of 0.5 mm to 30 mm.

4. The method for manufacturing the light-emitting device, according to claim 1, wherein the heating of the second substrate is performed with one of a heater, a lamp, and a voltage application to the second substrate.

5. The method for manufacturing the light-emitting device, according to claim 1, wherein one of the first electrode and the second electrode is formed of a light transmitting material.

6. The method for manufacturing the light-emitting device, according to claim 1, wherein the first electrode is formed of a reflective material, and the thickness of the first material layer varies depending on a color such that an emission color is changed by interference between the white light emitted from the second material layer and reflected light reflected on the first electrode.

7. The method for manufacturing the light-emitting device, according to claim 1, wherein the second electrode is formed of a reflective material, and the thickness of the first material layer varies depending on a color such that an emission color is changed by interference between the white light emitted from the second material layer and reflected light reflected on the second electrode.

8. The method for manufacturing the light-emitting device, according to claim 1, wherein the first material layer contains a metal oxide selected from the group consisting of molybdenum oxide, vanadium oxide, and rhenium oxide.

9. The method for manufacturing the light-emitting device, according to claim 1, wherein a mask is disposed between the first and second substrates.

10. The method for manufacturing the light-emitting device, according to claim 1, further comprising a step of patterning the layer containing the light-emitting material formed over the second substrate after forming the layer containing the light-emitting material.

11. A method for manufacturing a light-emitting device, the light-emitting device having at least a first light emitting element emitting a first color and a second light emitting element emitting a second color different from the first color, comprising steps of:
forming a first electrode over a first substrate;
forming selectively a first material layer over the first electrode by a droplet discharge method;
forming a layer containing a light-emitting material over a second substrate;
disposing the layer containing the light-emitting material formed over the second substrate and the first material layer formed over the first substrate so as to face each other;
heating the second substrate by lamp and vaporizing the layer containing the light-emitting material so that a second material layer containing the light-emitting material and emitting white light is formed over the first material layer; and
forming a second electrode over the second material layer,
wherein the first material layers of the first and second light-emitting elements have different film thicknesses, respectively.

12. The method for manufacturing the light-emitting device, according to claim 11, wherein the light-emitting device comprises a red-light-emitting element, a blue-light-emitting element, and a green-light-emitting element.

13. The method for manufacturing the light-emitting device, according to claim 11, wherein a distance between the first and second substrates is in a range of 0.5 mm to 30 mm.

14. The method for manufacturing the light-emitting device, according to claim 11, wherein the lamp is selected from the group consisting of a flash lamp, a xenon lamp, a metal halide lamp, a halogen lamp, and a tungsten lamp.

15. The method for manufacturing the light-emitting device, according to claim 11, wherein one of the first electrode and the second electrode is formed of a light transmitting material.

16. The method for manufacturing the light-emitting device, according to claim 11, wherein the first electrode is formed of a reflective material, and the thickness of the first material layer varies depending on a color such that an emission color is changed by interference between the white light emitted from the second material layer and reflected light reflected on the first electrode.

17. The method for manufacturing the light-emitting device, according to claim 11, wherein the second electrode is formed of a reflective material, and the thickness of the first material layer varies depending on a color such that an emission color is changed by interference between the white light emitted from the second material layer and reflected light reflected on the second electrode.

18. The method for manufacturing the light-emitting device, according to claim 11, wherein the first material layer contains a metal oxide selected from the group consisting of molybdenum oxide, vanadium oxide, and rhenium oxide.

19. The method for manufacturing the light-emitting device, according to claim 1, wherein a mask is disposed between the first and second substrates.

20. The method for manufacturing the light-emitting device, according to claim 1, further comprising a step of patterning the layer containing the light-emitting material formed over the second substrate after forming the layer containing the light-emitting material.

21. A method for manufacturing a light-emitting device, the light-emitting device having at least a first light emitting element emitting a first color and a second light emitting element emitting a second color different from the first color, comprising steps of:
forming a layer containing an organic compound over a conductive-surface plate in a first film-formation chamber;
forming a first material layer over a substrate having a first electrode in a second film-formation chamber;
holding the first material layer formed over the substrate and the layer containing the organic compound formed over the conductive-surface plate so as to face each other with a mask interposed therebetween in a third film-formation chamber;
evaporating the layer containing the organic compound formed over the conductive-surface plate by heating the conductive-surface plate so that a second material layer containing the organic compound and emitting white light is formed over the first material layer in the third film-formation chamber; and
forming a second electrode over the second material layer containing the organic compound in the third film-formation chamber,
wherein the first material layers of the first and second light-emitting elements have different film thicknesses, respectively.

22. The method for manufacturing the light-emitting device, according to claim 21, wherein the light-emitting device comprises a red-light-emitting element, a blue-light-emitting element, and a green-light-emitting element.

23. The method for manufacturing the light-emitting device, according to claim 21, wherein a distance between the first and second substrates is in a range of 0.5 mm to 30 mm.

24. The method for manufacturing the light-emitting device, according to claim 21, wherein the heating of the conductive-surface plate is performed with one of a heater, a lamp, and a voltage application to the conductive-surface plate.

25. The method for manufacturing the light-emitting device, according to claim 24, wherein the lamp is selected from the group consisting of a flash lamp, a xenon lamp, a metal halide lamp, a halogen lamp, and a tungsten lamp

26. The method for manufacturing the light-emitting device, according to claim 21, wherein one of the first electrode and the second electrode is formed of a light transmitting material.

27. The method for manufacturing the light-emitting device, according to claim 21, wherein the first electrode is formed of a reflective material, and the thickness of the first material layer varies depending on a color such that an emission color is changed by interference between the white light emitted from the second material layer and reflected light reflected on the first electrode.

28. The method for manufacturing the light-emitting device, according to claim 21, wherein the second electrode is formed of a reflective material, and the thickness of the first material layer varies depending on a color such that an emission color is changed by interference between the white light emitted from the second material layer and reflected light reflected on the second electrode.

29. The method for manufacturing the light-emitting device, according to claim 21, wherein the first material layer contains a metal oxide selected from the group consisting of molybdenum oxide, vanadium oxide, and rhenium oxide.

30. A method for manufacturing a light-emitting device, comprising steps of:
forming a layer containing an organic compound over one surface of a conductive-surface plate in a first film-formation chamber;
forming a first material layer over a substrate having a first electrode in a second film-formation chamber;
holding the first material layer formed over the substrate and the layer containing the organic compound formed over the conductive-surface plate so as to face each other with a mask interposed therebetween in a third film-formation chamber;
evaporating the layer containing the organic compound formed over the conductive-surface plate by heating the conductive-surface plate so that a second material layer containing the organic compound and emitting white light is formed over the first material layer in the third film-formation chamber;
forming a second electrode over the second material layer containing the organic compound in the third film-formation chamber;
taking out the substrate having the first electrode, the first and second material layers, and the second electrode from the third film-formation chamber; and
generating plasma between the mask and the conductive-surface plate in the third film-formation chamber.

31. The method for manufacturing a light-emitting device, according to claim 30, wherein the plasma is generated between the mask and the conductive-surface plate to clean an inner wall of the second film-formation chamber and surfaces of the mask and the conductive-surface plate.

32. The method for manufacturing a light-emitting device, according to claim 30, wherein the plasma is generated by exciting at least one kind of gas selected from Ar, H, F, NF₃, and O.
